(19) United States
(12) Patent Application Publication
(10) Pub. No.: US 2013/0233202 A1
(43) Pub. Date: Sep. 12, 2013

(54) INKS AND PROCESSES FOR PREPARING COPPER INDIUM GALLIUM SULFIDE/SELENIDE COATINGS AND FILMS

(71) Applicants: Yanyan Cao, Wilmington, DE (US); Jonathan V. Caspar, Wilmington, DE (US); John W. Catron, JR., Smyrna, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(72) Inventors: Yanyan Cao, Wilmington, DE (US); Jonathan V. Caspar, Wilmington, DE (US); John W. Catron, JR., Smyrna, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(73) Assignee: EI DU PONT DE NEMOURS AND COMPANY, Wilmington, DE (US)

(21) Appl. No.: 13/885,691

(22) PCT Filed: Dec. 1, 2011
(86) PCT No.: PCT/US11/62862

§ 371 Date: May 16, 2013

Related U.S. Application Data
(60) Provisional application No. 61/419,360, filed on Dec. 3, 2010.
(60) Provisional application No. 61/419,365, filed on Dec. 3, 2010.

(51) Int. Cl. C09D 11/00; H01L 31/18

(52) U.S. Cl. CPC C09D 11/00; H01L 31/18
USPC 106/31.13; 438/95

(57) ABSTRACT

This invention relates to inks comprising molecular precursors to copper indium gallium sulfide/selenide (CIGS/Se) and a plurality of particles. The inks are useful for preparing coatings and films of CIGS/Se on substrates. Such films are useful in the preparation of photovoltaic devices. This invention also relates to processes for preparing coated substrates and films and also to processes for making photovoltaic devices.

This application claims the benefit of U.S. Provisional Application No. 61/419,360, filed Dec. 3, 2010 and U.S. Provisional Application No. 61/419,365, filed Dec. 3, 2010 which are herein incorporated by reference.

### FIELD OF THE INVENTION

This invention relates to inks comprising molecular precursors to copper indium gallium sulfide/selenide (CIGS/Se) and a plurality of particles. The inks are useful for preparing coatings and films of CIGS/Se on substrates. Such films are useful in the preparation of photovoltaic devices. This invention also relates to processes for preparing coated substrates and films and also to processes for making photovoltaic devices.

### BACKGROUND

Semiconductors with a composition of Cu(In_{y}Ga_{1-y})(SₓSe₂₋ₓ) where 0<y≦1 and 0≦x≦2, collectively known as copper indium gallium sulfide/selenide or CIGS/Se, are some of the most promising candidates for thin-film photovoltaic applications due to their unique structural and electrical properties as energy absorber materials. However, current vacuum-based techniques to make CIGS/Se thin films (e.g., thermal evaporation, sputtering) require complicated equipment and therefore tend to be expensive. In addition, materials are wasted by deposition on chamber walls, and significant energy is required to evaporate or sputter materials from a source, often onto a heated substrate.

In contrast, solution-based processes to CIGS/Se are not only less expensive than vacuum-based processes, but typically have lower energy input and can utilize close to 100% of the raw materials by precisely and directly depositing materials on a substrate. In addition, solution-based processes are readily adaptable to high-throughput roll-to-roll processing on flexible substrates.

Solution-based processes to CIGS/Se fall into three general categories: (1) Electro-, electroless and chemical bath deposition where (electro)chemical reactions in a solution lead to the coating of an immersed substrate; (2) Particulate-based processes that use solid particles dispersed in a solvent to form an ink, which can be coated onto a substrate; and (3) Processes that coat molecular precursor solutions onto a substrate by mechanical means such as spraying or spin coating. In molecular precursor routes, the semiconductor can be synthesized in situ with direct film deposition from solution. High-boiling capping agents, which often introduce carbon-based impurities into the semiconductor film, are used in many particulate-based processes, but can be avoided in molecular precursor routes.

Molecular precursor routes to CIGS/Se have been reported using metal salts (e.g., chlorides and nitrates). For example, aqueous solutions of copper-, indium-, and gallium chlorides and an excess of thio- or selenourea have been deposited via spray pyrolysis to give CIGS/Se. By mixing salt solutions with binders or chelating agents, viscosity can be increased and deposition techniques other than spraying can be employed. However, these binders and chelating agents often introduce carbon-based impurities into the CIGS/Se film. In general, incorporation of CIGS/Se films made from salt-based precursors into photovoltaic devices has led to relatively low efficiencies, possibly due to chlorine- and oxygen-based impurities.

CuInSe₂ films have been formed from a solution of Cu and In naphthenates, wherein the naphthenates are derived from an acidic fraction of processed petroleum and are composed of a mixture of organic acids. The solutions were spun-coated onto substrates, which were then then treated with a 10% mixture of hydrogen in nitrogen gas at 450° C. and then selenized in vacuum-sealed ampoules with Se vapor to give coatings with a thickness of 250 nm.

The above molecular precursor routes rely on sulfo- and seleno-ureas or thioacetamide as the chalcogen source and/or annealing in reducing H₂, H₂S, S-, or Se-containing atmosphere for chalcogenization. A molecular precursor approach to CIGS/Se involving the preparation of a solution of copper and indium chalcogenides and elemental chalcogen has been reported. However, the use of hydrazine as the solvent was required. Hydrazine is a highly reactive and potentially explosive solvent that is described in the Merck Index as a “violent poison.” Single-source organometallic precursors to CIS/Se [e.g., (Ph₃P)₂Cu(mu-SEt)₂In(SEt)₂] have been prepared and used to form CIS/Se films via spray chemical vapor deposition. However, the synthesis of these single-source precursors is involved and limits the compositional tuning of film stoichiometry. In situ synthesis of films of CIS nanocrystals has been achieved by spin-coating butylamine solutions of indium acetate, copper chloride, thiourea, and propionic acid onto a substrate and heating at 250° C. Broad lines in the x-ray diffraction (XRD) analysis confirmed the nanocrystalline nature of the film.

Hence, there still exists a need for molecular precursor routes to CIGS/Se that involve simple, low-cost, scalable materials and processes with a low number of operations that provide high-quality, crystalline CIGS/Se films with tunable composition and morphology. There also exists a need for low-temperature routes to CIGS/Se using solvents and reagents with relatively low toxicity. In addition, there is a need for inks and processes to CIGS/Se that do not require annealing in a reducing H₂, H₂S, S-, or Se-containing atmosphere, and for inks that can be coated in a single coating operation to give films of suitable thickness for thin-film photovoltaic devices.

### SUMMARY

One aspect of this invention is an ink comprising:

a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof; and
   b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

Another aspect of this invention is a process comprising disposing an ink onto a substrate to form a coated substrate, wherein the ink comprises:

a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof; and
   b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

Another aspect of this invention is a coated substrate comprising:

A) a substrate; and
B) at least one layer disposed on the substrate comprising:

a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof; and
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and

b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

Another aspect of this invention is a coated substrate comprising:

(a) a substrate; and
(b) at least one layer disposed on the substrate comprising:
i) an inorganic matrix; and
ii) CIGS/Se microparticles characterized by an average longest dimension of 0.5-200 microns, wherein the microparticles are embedded in the inorganic matrix.

Another aspect of this invention is a film comprising:

a) an inorganic matrix; and
b) CIGS/Se microparticles characterized by an average longest dimension of 0.5-200 microns, wherein the microparticles are embedded in the inorganic matrix.

Another aspect of this invention is a photovoltaic cell comprising the film as described above.

Another aspect of this invention is a process for producing a photovoltaic cell.

### DETAILED DESCRIPTION

Herein, the terms “solar cell” and “photovoltaic cell” are synonymous unless specifically defined otherwise. These terms refer to devices that use semiconductors to convert visible and near-visible light energy into usable electrical energy. The terms “band gap energy,” “optical band gap,” and “band gap” are synonymous unless specifically defined otherwise. These terms refer to the energy required to generate electron-hole pairs in a semiconductor material, which in general is the minimum energy needed to excite an electron from the valence band to the conduction band.

Monograin layer (MGL) solar cells are a subclass of solar cells, and are also known as monocrystalline and monoparticle membrane solar cells. The MGL consists of monograin powder crystals embedded into an organic resin. A main technological advantage is that the absorber is fabricated separately from the solar cell, which leads to benefits in both the absorber- and cell-stages of MGL solar cell production. High temperatures are often preferred in adsorber material production, while lower temperatures are often preferred in the cell production. Fabricating the absorber and then embedding it in a matrix allows the possibility of using inexpensive, flexible, low-temperature substrates in the manufacture of inexpensive flexible solar cells.

Herein, an inorganic matrix replaces the organic matrix used in traditional MGL solar cells. As defined herein, “inorganic matrix” refers to a matrix comprising inorganic semiconductors, precursors to inorganic semiconductors, inorganic insulators, precursors to inorganic insulators, or mixtures thereof. Materials designated as inorganic matrixes can also contain small amounts of other materials, including dopants such as sodium, and organic materials. Examples of suitable inorganic matrixes include Cu(In,Ga)(S,Se)₂, Cu₂ZnSn(S,Se)₄, SiO₂, and precursors thereof. The inorganic matrix is used in combination with microparticles of chalcogenide semiconductor to build a coated film. In some embodiments, the bulk of the functionality comes from the microparticles, and the inorganic matrix plays a role in layer formation and enhancement of the layer performance. The longest dimension of the microparticles can be greater than the average thickness of the inorganic matrix and, in some instances, can span the coated thickness. The longest dimension of the microparticles can be less than or equivalent to the coated thickness, resulting in a film with completely or partially embedded microparticles. The microparticles and inorganic matrix can comprise different materials or can consist of essentially the same composition or can vary in composition, e.g., the chalcogenide or dopant composition can vary.

Herein, grain size refers to the diameter of a grain of granular material, wherein the diameter is defined as the longest distance between two points on its surface. In contrast, crystallite size is the size of a single crystal inside the grain. A single grain can be composed of several crystals. Herein, a useful method for obtaining grain size is electron microscopy. ASTM test methods are available for determining planar grain size, that is, characterizing the two-dimensional grain sections revealed by the sectioning plane. Manual grain size measurements are described in ASTM E 112 (equiaxed grain structures with a single size distribution) and E 1182 (specimens with a bi-modal grain size distribution), while ASTM E 1382 describes how any grain size type or condition can be measured using image analysis methods.

Herein, element groups are represented using CAS notation. As used herein, the term “chalcogen” refers to Group VIA elements, and the terms “metal chalcogenides” or “chalcogenides” refer to materials that comprise metals and Group VIA elements. Suitable Group VIA elements include sulfur, selenium and tellurium. Metal chalcogenides are important candidate materials for photovoltaic applications, since many of these compounds have optical band gap values well within the terrestrial solar spectra.

Herein, the term “binary-metal chalcogenide” refers to a chalcogenide composition comprising one metal. The term “ternary-metal chalcogenide” refers to a chalcogenide composition comprising two metals. The term “quaternary-metal chalcogenide” refers to a chalcogenide composition comprising three metals. The term “multinary-metal chalcogenide” refers to a chalcogenide composition comprising two or more metals, and encompasses ternary and quaternary metal chalcogenide compositions.

Herein, the terms “copper indium sulfide” and “CIS” refer to CuInS₂. “Copper indium selenide” and “CISe” refer to CuInSe₂. “Copper indium sulfide/selenide,” “CIS/Se,” and “CIS—Se” encompass all possible combinations of CuIn(S,Se)₂, including CuInS₂, CuInSe₂, and CuInSₓSe₂₋ₓ, where 0≦x≦2. Herein, the terms “copper indium gallium sulfide/selenide” and “CIGS/Se” and “GIGS—Se” encompass all possible combinations of Cu(In_{y}Ga_{1-y})(SₓSe₂₋ₓ), where 0<y≦1 and 0≦x≦2. The terms “CIS,” “CISe,” “CIS/Se,” and “CIGS/Se” further encompass copper indium gallium sulfide/selenide semiconductors with fractional stoichiometries, e.g., Cu_{0.7}In_{1.1}S₂. That is, the stoichiometry of the elements can vary from a strictly 1:1:2 molar ratio for Cu:(In+Ga):(S+Se). Materials designated as CIGS/Se can also contain small amounts of other elements such as sodium. In addition, the Cu and In in CIS/Se and CIGS/Se can be partially substituted by other metals. That is, Cu can be partially replaced by Ag and/or Au, and In by B, Al, and/or Tl. Highly efficient CIGS/Se solar cells are often copper-poor, that is the molar ratio of Cu:(In+Ga) is less than one.

As used herein, “coherent domain size” refers to the size of crystalline domains over which a defect-free, coherent structure exists. The coherency comes from the fact that the three-dimensional ordering is not broken inside of these domains. When the coherent grain size is less than about 100 nm, appreciable broadening of the x-ray diffraction lines will occur. The domain size can be estimated by measuring the full width at half maximum intensity of the diffraction peak.

Herein, the terms “nanoparticle,” “nanocrystal,” and “nanocrystalline particle” are synonymous unless specifically defined otherwise, and are meant to include nanoparticles with a variety of shapes that are characterized by an average longest dimension of about 1 nm to about 500 nm. Herein, by nanoparticle “size” or “size range” or “size distribution,” we mean that the average longest dimension of a plurality of nanoparticles falls within the range. “Longest dimension” is defined herein as the measurement of a nanoparticle from end to end. The “longest dimension” of a particle will depend on the shape of the particle. For example, for particles that are roughly or substantially spherical, the longest dimension will be a diameter of the particle. For other particles, the longest dimension will be a diagonal or a side.

Herein, the terms “microparticle,” “microcrystal,” and “microcrystalline particle” are synonymous unless specifically defined otherwise and are meant to include microparticles with a variety of shapes that are characterized by an average longest dimension of at least about 0.5 micron to about 200 microns. Herein, microparticle “size,” “size range,” or “size distribution” are defined the same as described above for nanoparticles.

As defined herein, “coated particles” refers to particles that have a surface coating of organic or inorganic material. Methods for surface-coating inorganic particles are well-known in the art. As defined herein, the terms “surface coating” and “capping agent” are used synonymously and refer to a strongly absorbed or chemically bonded monolayer of organic or inorganic molecules on the surface of the particle(s). In addition to carbon and hydrogen, suitable organic capping agents can comprise functional groups, including nitrogen-, oxygen-, sulfur-, selenium-, or phosphorus-based functional groups. Suitable inorganic capping agents can comprise chalcogenides, including metal chalcogenides, or zintl ions, wherein zintl ions refers to homopolyatomic anions and heteropolyatomic anions that have intermetallic bonds between the same or different metals of the main group, transition metals, lanthanides, and/or actinides.

Elemental and metal chalcogenide particles can be composed only of the specified elements or can be doped with small amounts of other elements. As used herein, the term “alloy” refers to a substance that is a mixture, as by fusion, of two or more metals. Herein, all reference to wt % of particles is meant to include the surface coating. Many suppliers of nanoparticles use undisclosed or proprietary surface coatings that act as dispersing aids. Herein, all reference to wt % of particles is meant to include the undisclosed or proprietary coatings that the manufacturer may have added as a dispersant aid. For instance, a commercial copper nanopowder is considered nominally 100 wt % copper.

Herein, the term “metal salts” refers to compositions wherein metal cations and inorganic anions are joined by ionic bonding. Relevant classes of inorganic anions comprise oxides, sulfides, selenides, carbonates, sulfates and halides. Herein, the term “metal complexes” refers to compositions wherein a metal is bonded to a surrounding array of molecules or anions, typically called “ligands” or “complexing agents.” The atom within a ligand that is directly bonded to the metal atom or ion is called the “donor atom” and, herein, often comprises nitrogen, oxygen, selenium, or sulfur.

Herein, ligands are classified according to M. L. H. Green's “Covalent Bond Classification (CBC) Method.” An “X-function ligand” is one which interacts with a metal center via a normal two-electron covalent bond, composed of one electron from the metal and one electron from the X ligand. Simple examples of X-type ligands include alkyls and thiolates. Herein, the term “nitrogen-, oxygen-, carbon-, sulfur-, or selenium-based organic ligands” refers specifically to carbon-containing X-function ligands, wherein the donor atom comprises nitrogen, oxygen, carbon, sulfur, or selenium. Herein, the term “complexes of nitrogen-, oxygen-, carbon-, sulfur-, or selenium-based organic ligands” refers to the metal complexes comprising these ligands. Examples include metal complexes of amidos, alkoxides, acetylacetonates, acetates, carboxylates, hydrocarbyls, O-, N-, S-, Se- or halogen-substituted hydrocarbyls, thiolates, selenolates, thiocarboxylates, selenocarboxylates, dithiocarbamates, and diselenocarbamates.

As defined herein, a “hydrocarbyl group” is a univalent group containing only carbon and hydrogen. Examples of hydrocarbyl groups include unsubstituted alkyls, cycloalkyls, and aryl groups, including alkyl-substituted aryl groups. Suitable hydrocarbyl groups and alkyl groups contain 1 to about 30 carbons, or 1 to 25, 1 to 20, 1 to 15, 1 to 10, 1 to 5, 1 to 4, or 1 to 2 carbons. By “heteroatom-substituted hydrocarbyl” is meant a hydrocarbyl group that contains one or more heteroatoms wherein the free valence is located on carbon, not on the heteroatom. Examples include hydroxyethyl and carbomethoxyethyl. Suitable heteroatom substituents include O-, N-, S-, Se-, halogen, and tri(hydrocarbyl)silyl. In a substituted hydrocarbyl, all of the hydrogens can be substituted, as in trifluoromethyl. Herein, the term “tri(hydrocarbyl)silyl” encompasses silyl substituents, wherein the substituents on silicon are hydrocarbyls. Herein, by “O-, N-, S-, or Se-based functional groups” is meant univalent groups other than hydrocarbyl and substituted hydrocarbyl that comprise O-, N-, S-, or Se-heteroatoms, wherein the free valence is located on this heteroatom. Examples of O-, N-, S-, and Se-based functional groups include alkoxides, amidos, thiolates, and selenolates.

### Inks

One aspect of this invention is an ink comprising:

a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof; and
   b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

In some embodiments, the copper source is selected from the group consisting of copper complexes of nitrogen-, oxygen-, carbon-, sulfur-, or selenium-based organic ligands and mixtures thereof.

In some embodiments, the copper source is selected from the group consisting of copper sulfides, copper selenides, and mixtures thereof.

In some embodiments, the indium source is selected from the group consisting of indium complexes of nitrogen-, oxygen-, carbon-, sulfur-, or selenium-based organic ligands and mixtures thereof.

In some embodiments, the indium source is selected from the group consisting of indium sulfides, indium selenides, and mixtures thereof.

In some embodiments, the copper source is selected from the group consisting of copper complexes of nitrogen-, oxygen-, carbon-, sulfur-, or selenium-based organic ligands and mixtures thereof and the indium source is selected from the group consisting of indium complexes of nitrogen-, oxygen-, carbon-, sulfur-, or selenium-based organic ligands and mixtures thereof.

In some embodiments, the copper source is selected from the group consisting of copper complexes of nitrogen-, oxygen-, carbon-, sulfur-, or selenium-based organic ligands and mixtures thereof and the indium source is selected from the group consisting of indium sulfides, indium selenides, and mixtures thereof.

In some embodiments, the copper source is selected from the group consisting of copper sulfides, copper selenides, and mixtures thereof and the indium source is selected from the group consisting of indium complexes of nitrogen-, oxygen-, carbon-, sulfur-, or selenium-based organic ligands and mixtures thereof.

Chalcogen Compounds.

In some embodiments, the molecular precursor further comprises a chalcogen compound. In some embodiments, the copper source is selected from the group consisting of copper complexes of nitrogen-, oxygen-, carbon-, sulfur-, or selenium-based organic ligands and mixtures thereof, or the indium source is selected from the group consisting of indium complexes of nitrogen-, oxygen-, carbon-, sulfur-, or selenium-based organic ligands and mixtures thereof, and the molecular precursor further comprises a chalcogen compound. In some embodiments, the copper or indium source comprises a nitrogen-, oxygen-, or carbon-based organic ligand, and the molecular precursor further comprises a chalcogen compound. In some embodiments, the copper and indium sources comprise a nitrogen-, oxygen-, or carbon-based organic ligand, and the molecular precursor further comprises a chalcogen compound.

Suitable chalcogen compounds include: elemental S, elemental Se, CS₂, CSe₂, CSSe, R¹S—Z, R¹Se—Z, R¹S—SR¹, R¹Se—SeR¹, R²C(S)S—Z, R²C(Se)Se—Z, R²C(Se)S—Z, R¹C(O)S—Z, R¹C(O)Se—Z, and mixtures thereof, wherein each Z is independently selected from the group consisting of: H, NR⁴₄, and SiR⁵₃; wherein each R¹ and R⁵ is independently selected from the group consisting of: hydrocarbyl and O-, N-, S-, Se-, halogen- or tri(hydrocarbyl)silyl-substituted hydrocarbyl; each R² is independently selected from the group consisting of hydrocarbyl, O-, N-, S-, Se-, halogen-, or tri(hydrocarbyl)silyl-substituted hydrocarbyl, and O-, N-, S-, or Se-based functional groups; and each R⁴ is independently selected from the group consisting of hydrogen, O-, N-, S-, Se-, halogen- or tri(hydrocarbyl)silyl-substituted hydrocarbyl, and O-, N-, S-, or Se-based functional groups. In some embodiments, elemental sulfur, elemental selenium, or a mixture of elemental sulfur and selenium is present.

For the chalcogen compounds, suitable R¹S— and R¹Se— of R¹S—Z and R¹Se—Z are selected from the following lists of suitable thiolates and selenolates.

For the chalcogen compounds, suitable R¹S—SR¹ and R¹Se—SeR¹ include: methyl disulfide, 2,2′-dipyridyl disulfide, (2-thienyl)disulfide, (2-hydroxyethyl)disulfide, (2-methyl-3-furyl)disulfide, (6-hydroxy-2-naphthyl)disulfide, ethyl disulfide, methylpropyl disulfide, allyl disulfide, propyl disulfide, isopropyl disulfide, butyl disulfide, sec-butyl disulfide, (4-methoxyphenyl)disulfide, benzyl disulfide, p-tolyl disulfide, phenylacetyl disulfide, tetramethylthiuram disulfide, tetraethylthiuram disulfide, tetrapropylthiuram disulfide, tetrabutylthiuram disulfide, methylxanthic disulfide, ethylxanthic disulfide, i-propylxanthic disulfide, benzyl diselenide, methyl diselenide, ethyl diselenide, phenyl diselenide, and mixtures thereof.

For the chalcogen compounds, suitable R²C(S)S—Z, R²C(Se)Se—Z, R²C(Se)S—Z, R¹C(O)S—Z, and R¹C(O)Se—Z are selected from the ligand lists (below) of suitable thio-, seleno-, and dithiocarboxylates; suitable dithio-, diseleno-, and thioselenocarbamates; and suitable dithioxanthogenates.

Suitable NR⁴₄ include: Et₂NH₂, ELM, Et₃NH, EtNH₃, NH₄, Me₂NH₂, Me₄N, Me₃NH, MeNH₃, Pr₂NH₂, Pr₄N, Pr₃NH, PrNH₃, Bu₃NH, Me₂PrNH, (i-Pr)₃NH, and mixtures thereof.

Suitable SiR⁵₃ include: SiMe₃, SiEt₃, SiPr₃, SiBu₃, Si(i-Pr)₃, SiEtMe₂, SiMe₂(i-Pr), Si(t-Bu)Me₂, Si(cyclohexyl)Me₂, and mixtures thereof.

Many of these chalcogen compounds are commercially available or readily synthesized by the addition of an amine, alcohol, or alkyl nucleophile to CS₂ or CSe₂ or CSSe.

Molar Ratios of the Ink.

In some embodiments, the molar ratio of Cu:(In+Ga) is about 1 in the ink. In some embodiments, the molar ratio of Cu:(In+Ga) is less than 1. In some embodiments, the molar ratio of total chalcogen to (Cu+In+Ga) is at least about 1 in the ink.

As defined herein, sources for the total chalcogen include the metal chalcogenides (e.g., the copper, indium, and gallium sulfides and selenides of the molecular precursor, the CIGS/Se particles, and the binary and ternary Cu-, In-, or Ga-containing chalcogenide particles), the sulfur- and selenium-based organic ligands and the optional chalcogen compound of the molecular precursor.

As defined herein, the moles of total chalcogen are determined by multiplying the moles of each metal chalcogenide by the number of equivalents of chalcogen that it contains and then summing these quantities together with the number of moles of any sulfur or selenium-based organic ligands and optional chalcogen compound. Each sulfur- or selenium-based organic ligand and compound is assumed to contribute just one equivalent of chalcogen in this determination of total chalcogen. This is because not all of the chalcogen atoms contained within each ligand and compound will necessarily be available for incorporation into CIGS/Se; some of the chalcogen atoms from these sources can be incorporated into organic by-products.

The moles of (Cu+In+Ga) are determined by multiplying the moles of each Cu-, In-, or Ga-containing species by the number of equivalents of Cu, In, or Ga that it contains and then summing these quantities. As an example, the molar ratio of total chalcogen to (Cu+In+Ga) for an ink comprising indium(III) acetate, copper(II) dimethyldithiocarbamate (CuDTC), 2-mercaptoethanol (MCE), sulfur, Cu₂S particles, and In particles=[2(moles of CuDTC)+(moles of MCE)+(moles of S)+(moles of Cu₂S)]/[(moles of In acetate)+(moles of CuDTC)+2(moles of Cu₂S)+(moles of In)].

### Molecular Precursor

Molar Ratios of the Molecular Precursor.

In some embodiments, the molar ratio of Cu:(In+Ga) is about 1 in the molecular precursor. In some embodiments, the molar ratio of Cu:(In+Ga) is less than 1. In some embodiments, the molar ratio of total chalcogen to (Cu+In+Ga) is at least about 1 in the molecular precursor.

As defined herein, the moles of total chalcogen and the moles of (Cu+In+Ga) are determined as defined above for the ink.

In some embodiments, elemental sulfur, elemental selenium, or a mixture of elemental sulfur and selenium is present in the molecular precursor, and the molar ratio of elemental (S+Se) is about 0.2 to about 5, or about 0.5 to about 2.5, relative to the copper source of the molecular precursor.

Organic Ligands.

In some embodiments, the nitrogen-, oxygen-, carbon-, sulfur- or selenium-based organic ligands are selected from the group consisting of: amidos; alkoxides; acetylacetonates; carboxylates; hydrocarbyls; O-, N-, S-, Se-, halogen-, or tri(hydrocarbyl)silyl-substituted hydrocarbyls; thiolates and selenolates; thio-, seleno-, and dithiocarboxylates; dithio-, diseleno-, and thioselenocarbamates; and dithioxanthogenates. Many of these are commercially available or readily synthesized by the addition of an amine, alcohol, or alkyl nucleophile to CS₂ or CSe₂ or CSSe.

Amidos. Suitable amidos include: bis(trimethylsilyl)amino, dimethylamino, diethylamino, diisopropylamino, N-methyl-t-butylamino, 2-(dimethylamino)-N-methylethylamino, N-methylcyclohexylamino, dicyclohexylamino, N-ethyl-2-methylallylamino, bis(2-methoxyethyl)amino, 2-methylaminomethyl-1,3-dioxolane, pyrrolidino, t-butyl-1-piperazinocarboxylate, N-methylanilino, N-phenylbenzylamino, N-ethyl-o-toluidino, bis(2,2,2-trifluoromethyl)amino, N-t-butyltrimethylsilylamino, and mixtures thereof. Some ligands can chelate the metal center, and, in some cases, comprise more than one type of donor atom, e.g., the dianion of N-benzyl-2-aminoethanol is a suitable ligand comprising both amino and alkoxide groups.

Alkoxides. Suitable alkoxides include: methoxide, ethoxide, n-propoxide, i-propoxide, n-butoxide, t-butoxide, neopentoxide, ethylene glycol dialkoxide, 1-methylcyclopentoxide, 2-fluoroethoxide, 2,2,2-trifluoroethoxide, 2-ethoxyethoxide, 2-methoxyethoxide, 3-methoxy-1-butoxide, methoxyethoxyethoxide, 3,3-diethoxy-1-propoxide, 2-dimethylaminoethoxide, 2-diethylaminoethoxide, 3-dimethylamino-1-propoxide, 3-diethylamino-1-propoxide, 1-dimethylamino-2-propoxide, 1-diethylamino-2-propoxide, 2-(1-pyrrolidinyl)ethoxide, 1-ethyl-3-pyrrolidinoxide, 3-acetyl-1-propoxide, 4-methoxyphenoxide, 4-chlorophenoxide, 4-t-butylphenoxide, 4-cyclopentylphenoxide, 4-ethylphenoxide, 3,5-bis(trifluoromethyl)phenoxide, 3-chloro-5-methoxyphenoxide, 3,5-dimethoxyphenoxide, 2,4,6-trimethylphenoxide, 3,4,5-trimethylphenoxide, 3,4,5-trimethoxyphenoxide, 4-t-butyl-catecholate(2-), 4-propanoylphenoxide, 4-(ethoxycarbonyl)phenoxide, 3-(methylthio)-1-propoxide, 2-(ethylthio)-1-ethoxide, 2-(methylthio)ethoxide, 4-(methylthio)-1-butoxide, 3-(methylthio)-1-hexoxide, 2-methoxybenzylalkoxide, 2-(trimethylsilyl)ethoxide, (trimethylsilyl)methoxide, 1-(trimethylsilyl)ethoxide, 3-(trimethylsilyl)propoxide, 3-methylthio-1-propoxide, and mixtures thereof.

Acetylacetonates. Herein, the term acetylacetonate refers to the anion of 1,3-dicarbonyl compounds, A¹C(O)CH(A²)C(O)A¹, wherein each A¹ is independently selected from hydrocarbyl, substituted hydrocarbyl, and O-, S-, and N-based functional groups and each A² is independently selected from hydrocarbyl, substituted hydrocarbyl, halogen, and O-, S-, and N-based functional groups. Suitable acetylacetonates include: 2,4-pentanedionate, 3-methyl-2-4-pentanedionate, 3-ethyl-2,4-pentanedionate, 3-chloro-2,4-pentanedionate, 1,1,1-trifluoro-2,4-pentanedionate, 1,1,1,5,5,5-hexafluoro-2,4-pentanedionate, 1,1,1,5,5,6,6,6-octafluoro-2,4-hexanedionate, ethyl 4,4,4-trifluoroacetoacetate, 2-methoxyethylacetoacetate, methylacetoacetate, ethylacetoacetate, t-butylacetoacetate, 1-phenyl-1,3-butanedionate, 2,2,6,6-tetramethyl-3,5-heptanedionate, allyloxyethoxytrifluoroacetoacetate, 4,4,4-trifluoro-1-phenyl-1,3-butanedionate, 1,3-diphenyl-1,3-propanedionate, 6,6,7,7,8,8,8-heptafluoro-2-2-dimethyl-3,5-octanedionate, and mixtures thereof.

Carboxylates.

Suitable carboxylates include: formate, acetate, trifluoroacetate, propionate, butyrates, hexanoate, octanoate, decanoate, stearate, isobutyrate, t-butylacetate, heptafluorobutyrate, methoxyacetate, ethoxyacetate, methoxypropionate, 2-ethyl hexanoate, 2-(2-methoxyethoxy)acetate, 2-[2-(2-methoxyethoxy)ethoxy]acetate, (methylthio)acetate, tetrahydro-2-furoate, 4-acetyl butyrate, phenylacetate, 3-methoxyphenylacetate, (trimethylsilyl)acetate, 3-(trimethylsilyl)propionate, maleate, benzoate, acetylenedicarboxylate, and mixtures thereof.

Hydrocarbyls.

Suitable hydrocarbyls include: methyl, ethyl, n-propyl, i-propyl, n-butyl, i-butyl, sec-butyl, t-butyl, n-pentyl, n-hexyl, n-heptyl, n-octyl, neopentyl, 3-methylbutyl, phenyl, benzyl, 4-t-butylbenzyl, 4-t-butylphenyl, p-tolyl, 2-methyl-2-phenylpropyl, 2-mesityl, 2-phenylethyl, 2-ethylhexyl, 2-methyl-2-phenylpropyl, 3,7-dimethyloctyl, allyl, vinyl, cyclopentyl, cyclohexyl, and mixtures thereof.

Substituted Hydrocarbyls. Suitable O-, N-, S-, Se-, halogen- or tri(hydrocarbyl)silyl-substituted hydrocarbyls include: 2-methoxyethyl, 2-ethoxyethyl, 4-methoxyphenyl, 2-methoxybenzyl, 3-methoxy-1-butyl, 1,3-dioxan-2-ylethyl, 3-trifluoromethoxyphenyl, 3,4-(methylenedioxy)phenyl, 2,4-dimethoxyphenyl, 2,5-dimethoxyphenyl, 3,4-dimethoxyphenyl, 2-methoxybenzyl, 3-methoxybenzyl, 4-methoxybenzyl, 3,5-dimethoxyphenyl, 3,5-dimethyl-4-methoxyphenyl, 3,4,5-trimethoxyphenyl, 4-methoxyphenethyl, 3,5-dimethoxybenzyl, 4-(2-tetrahydro-2H-pyranoxy)phenyl, 4-phenoxyphenyl, 2-benzyloxyphenyl, 3-benzyloxyphenyl, 4-benzyloxyphenyl, 3-fluoro-4-methoxyphenyl, 5-fluoro-2-methoxyphenyl, 2-ethoxyethenyl, 1-ethoxyvinyl, 3-methyl-2-butenyl, 2-furyl, carbomethoxyethyl, 3-dimethylamino-1-propyl, 3-diethylamino-1-propyl, 3-[bis(trimethylsilyl)amino]phenyl, 4-(N,N-dimethyl)aniline, [2-(1-pyrrolidinylmethyl)phenyl], [3-(1-pyrrolidinylmethyl)phenyl], [4-(1-pyrrolidinylmethyl)phenyl], [2-(4-morpholinylmethyl)phenyl], [3-(4-morpholinylmethyl)phenyl], [4-(4-morpholinylmethyl)phenyl], (4-(1-piperidinylmethyl)phenyl), (2-(1-piperidinylmethyl)phenyl), (3-(1-piperidinylmethyl)phenyl), 3-(1,4-dioxa-8-azaspiro[4,5]dec-8-ylmethyl)phenyl, 1-methyl-2-pyrrolyl, 2-fluoro-3-pyridyl, 6-methoxy-2-pyrimidyl, 3-pyridyl, 5-bromo-2-pyridyl, 1-methyl-5-imidazolyl, 2-chloro-5-pyrimidyl, 2,6-dichloro-3-pyrazinyl, 2-oxazolyl, 5-pyrimidyl, 2-pyridyl, 2-(ethylthio)ethyl, 2-(methylthio)ethyl, 4-(methylthio)butyl, 3-(methylthio)-1-hexyl, 4-thioanisole, 4-bromo-2-thiazolyl, 2-thiophenyl, chloromethyl, 4-fluorophenyl, 3-fluorophenyl, 4-chlorophenyl, 3-chlorophenyl, 4-fluoro-3-methylphenyl, 4-fluoro-2-methylphenyl, 4-fluoro-3-methylphenyl, 5-fluoro-2-methylphenyl, 3-fluoro-2-methylphenyl, 4-chloro-2-methylphenyl, 3-fluoro-4-methylphenyl, 3,5-bis(trifluoromethyl)-phenyl, 3,4,5-trifluorophenyl, 3-chloro-4-fluorophenyl, 3-chloro-5-fluorophenyl, 4-chloro-3-fluorophenyl, 3,4-dichlorophenyl, 3,5-dichlorophenyl, 3,4-difluorophenyl, 3,5-difluorophenyl, 2-bromobenzyl, 3-bromobenzyl, 4-fluorobenzyl, perfluoroethyl, 2-(trimethylsilyl)ethyl, (trimethylsilyl)methyl, 3-(trimethylsilyl)propyl, and mixtures thereof.

Thiolates and Selenolates.

Suitable thiolates and selenolates include: 1-thioglycerol, phenylthio, ethylthio, methylthio, n-propylthio, i-propylthio, n-butylthio, i-butylthio, t-butylthio, n-pentylthio, n-hexylthio, n-heptylthio, n-octylthio, n-nonylthio, n-decylthio, n-dodecylthio, 2-methoxyethylthio, 2-ethoxyethylthio, 1,2-ethanedithiolate, 2-pyridinethiolate, 3,5-bis(trifluoromethyl)benzenethiolate, toluene-3,4-dithiolate, 1,2-benzenedithiolate, 2-dimethylaminoethanethiolate, 2-diethylaminoethanethiolate, 2-propene-1-thiolate, 2-hydroxythiolate, 3-hydroxythiolate, methyl-3-mercaptopropionate anion, cyclopentanethiolate, 2-(2-methoxyethoxy)ethanethiolate, 2-(trimethylsilyl)ethanethiolate, pentafluorophenylthiolate, 3,5-dichlorobenzenethiolate, phenylthiolate, cyclohexanethiolate, 4-chlorobenzenemethanethiolate, 4-fluorobenzenemethanethiolate, 2-methoxybenzenethiolate, 4-methoxybenzenethiolate, benzylthiolate, 3-methylbenzylthiolate, 3-ethoxybenzenethiolate, 2,5-dimethoxybenzenethiolate, 2-phenylethanethiolate, 4-t-butylbenzenethiolate, 4-t-butylbenzylthiolate, phenylselenolate, methylselenolate, ethylselenolate, n-propylselenolate, i-propylselenolate, n-butylselenolate, i-butylselenolate, t-butylselenolate, pentylselenolate, hexylselenolate, octylselenolate, benzylselenolate, and mixtures thereof.

Carboxylates, Carbamates, and Xanthogenates.

Suitable thio-, seleno-, and dithiocarboxylates include: thioacetate, thiobenzoate, selenobenzoate, dithiobenzoate, and mixtures thereof. Suitable dithio-, diseleno-, and thioselenocarbamates include: dimethyldithiocarbamate, diethyldithiocarbamate, dipropyldithiocarbamate, dibutyldithiocarbamate, bis(hydroxyethyl)dithiocarbamate, dibenzyldithiocarbamate, dimethyldiselenocarbamate, diethyldiselenocarbamate, dipropyldiselenocarbamate, dibutyldiselenocarbamate, dibenzyldiselenocarbamate, and mixtures thereof. Suitable dithioxanthogenates include: methylxanthogenate, ethylxanthogenate, i-propylxanthogenate, and mixtures thereof.

Vehicle.

The molecular precursor comprises a vehicle, comprising a liquid chalcogen compound, a solvent, or a mixture thereof. In some embodiments, the vehicle comprises about 99 to about 1 wt %, 95 to about 5 wt %, 90 to 10 wt %, 80 to 20 wt %, 70 to 30 wt %, or 60 to 40 wt % of the molecular precursor, based upon the total weight of the molecular precursor. In some embodiments, the vehicle comprises at least about 2 wt %, 5 wt %, 10 wt %, 20 wt %, 30 wt %, 40 wt %, 50 wt %, 60 wt %, 70 wt %, 80 wt %, 90 wt %, or 95 wt % of the molecular precursor, based upon the total weight of the molecular precursor. In some embodiments, the vehicle comprises a liquid chalcogen compound.

Solvents.

In some embodiments, the vehicle comprises a solvent. In some embodiments, the boiling point of the solvent is greater than about 100° C., 110° C., 120° C., 130° C., 140° C., 150° C., 160° C., 170° C., 180° C. or 190° C. at atmospheric pressure. In some embodiments, the process is conducted at atmospheric pressure. Suitable solvents include: aromatics, heteroaromatics, nitriles, amides, alcohols, pyrrolidinones, amines, and mixtures thereof. Suitable heteroaromatics include pyridine and substituted pyridines. Suitable amines include compounds of the form R⁶NH₂, wherein each R⁶ is independently selected from the group consisting of: O-, N-, S-, or Se-substituted hydrocarbyl. In some embodiments, the solvent comprises an amino-substituted pyridine.

Aromatics.

Suitable aromatic solvents include: benzene, toluene, ethylbenzene, chlorobenzene, o-xylene, m-xylene, p-xylene, mesitylene, i-propylbenzene, 1-chlorobenzene, 2-chlorotoluene, 3-chlorotoluene, 4-chlorotoluene, t-butylbenzene, n-butylbenzene, i-butylbenzene, s-butylbenzene, 1,2-dichlorobenzene, 1,3-dichlorobenzene, 1,4-dichlorobenzene, 1,3-diisopropylbenzene, 1,4-diisopropylbenzene, 1,2-difluorobenzene, 1,2,4-trichlorobenzene, 3-methylanisole, 3-chloroanisole, 3-phenoxytoluene, diphenylether, and mixtures thereof.

Heteroaromatics.

Suitable heteroaromatic solvents include: pyridine, 2-picoline, 3-picoline, 3,5-lutidine, 4-t-butylpyridine, 2-aminopyridine, 3-aminopyridine, diethylnicotinamide, 3-cyanopyridine, 3-fluoropyridine, 3-chloropyridine, 2,3-dichloropyridine, 2,5-dichloropyridine, 5,6,7,8-tetrahydroisoquinoline, 6-chloro-2-picoline, 2-methoxypyridine, 3-(aminomethyl)pyridine, 2-amino-3-picoline, 2-amino-6-picoline, 2-amino-2-chloropyridine, 2,3-diaminopyridine, 3,4-diaminopyridine, 2-(methylamino)pyridine, 2-dimethylaminopyridine, 2-(aminomethyl)pyridine, 2-(2-aminoethyl)pyridine, 2-methoxypyridine, 2-butoxypyridine, and mixtures thereof.

Nitriles.

Suitable nitrile solvents include: acetonitrile, 3-ethoxypropionitrile, 2,2-diethoxypropionitrile, 3,3-diethoxypropionitrile, diethoxyacetonitrile, 3,3-dimethoxypropionitrile, 3-cyanopropionaldehyde dimethylacetal, dimethylcyanamide, diethylcyanamide, diisopropylcyanamide, 1-pyrrolidinecarbonitrile, 1-piperidinecarbonitrile, 4-morpholinecarbonitrile, methylaminoacetonitrile, butylaminoacetonitrile, dimethylaminoacetonitrile, diethylaminoacetonitrile, N-methyl-beta-alaninenitrile, 3,3′-iminopropionitrile, 3-(dimethylamino)propionitrile, 1-piperidinepropionitrile, 1-pyrrolidinebutyronitrile, propionitrile, butyronitrile, valeronitrile, isovaleronitrile, 3-methoxypropionitrile, 3-cyanopyridine, 4-amino-2-chlorobenzonitrile, 4-acetylbenzonitrile, and mixtures thereof.

Amides.

Suitable amide solvents include: N,N-diethylnicotinamide, N-methylnicotinamide, N,N-dimethylformamide, N,N-diethylformamide, N,N-diisopropylformamide, N,N-dibutylformamide, N,N-dimethylacetamide, N,N-diethylacetamide, N,N-diisopropylacetamide, N,N-dimethylpropionamide, N,N-diethylpropionamide, N,N,2-trimethylpropionamide, acetamide, propionamide, isobutyramide, trimethylacetamide, nipecotamide, N,N-diethylnipecotamide, and mixtures thereof.

Alcohols.

Suitable alcohol solvents include: methoxyethoxyethanol, methanol, ethanol, isopropanol, 1-butanol, 2-pentanol, 2-hexanol, 2-octanol, 2-nonanol, 2-decanol, 2-dodecanol, ethylene glycol, 1,3-propanediol, 2,3-butanediol, 1,5-pentanediol, 1,6-hexanediol, 1,7-heptanediol, 1,8-octanediol, cyclopentanol, cyclohexanol, cyclopentanemethanol, 3-cyclopentyl-1-propanol, 1-methylcyclopentanol, 3-methylcyclopentanol, 1,3-cyclopentanediol, 2-cyclohexylethanol, 1-cyclohexylethanol, 2,3-dimethylcyclohexanol, 1,3-cyclohexanediol, 1,4-cyclohexanediol, cycloheptanol, cyclooctanol, 1,5-decalindiol, 2,2-dichloroethanol, 2,2,2-trifluoroethanol, 2-methoxyethanol, 2-ethoxyethanol, 2-propoxyethanol, 2-butoxyethanol, 3-ethoxy-1-propanol, propyleneglycol propyl ether, 3-methoxy-1-butanol, 3-methoxy-3-methyl-1-butanol, 3-ethoxy-1,2-propanediol, di(ethyleneglycol) ethylether, diethylene glycol, 2,4-dimethylphenol, and mixtures thereof.

Pyrrolidinones.

Suitable pyrrolidinone solvents include: N-methyl-2-pyrrolidinone, 5-methyl-2-pyrrolidinone, 3-methyl-2-pyrrolidinone, 2-pyrrolidinone, 1,5-dimethyl-2-pyrrolidinone, 1-ethyl-2-pyrrolidinone, 1-(2-hydroxyethyl)-2-pyrrolidinone, 5-methoxy-2-pyrrolidinone, 1-(3-aminopropyl)-2-pyrrolidinone, and mixtures thereof.

Amines.

Suitable amine solvents include: butylamine, hexylamine, octylamine, 3-methoxypropylamine, 2-methylbutylamine, isoamylamine, 1,2-dimethylpropylamine, hydrazine, ethylenediamine, 1,3-diaminopropane, 1,2-diaminopropane, 1,2-diamino-2-methylpropane, 1,3-diaminopentane, 1,1-dimethylhydrazine, N-ethylmethylamine, diethylamine, N-methylpropylamine, diisopropylamine, dibutylamine, triethylamine, N-methylethylenediamine, N-ethylethylenediamine, N-propylethylenediamine, N-isopropylethylenediamine, N,N′-dimethylethylenediamine, N,N-dimethylethylenediamine, N,N′-diethylethylenediamine, N,N-diethylethylenediamine, N,N-diisopropylethylenediamine, N,N-dibutylethylenediamine, N,N,N′-trimethylethylenediamine, 3-dimethylaminopropylamine, 3-diethylaminopropylamine, diethylenetriamine, cyclohexylamine, bis(2-methoxyethyl)amine, aminoacetaldehyde diethyl acetal, methylaminoacetaldehyde dimethyl acetal, N,N-dimethylacetamide dimethyl acetal, dimethylaminoacetaldehyde diethyl acetal, diethylaminoacetaldehyde diethyl acetal, 4-aminobutyraldehyde diethyl acetal, 2-methylaminomethyl-1,3-dioxolane, ethanolamine, 3-amino-1-propanol, 2-hydroxyethylhydrazine, N,N-diethylhydroxylamine, 4-amino-1-butanol, 2-(2-aminoethoxy)ethanol, 2-(methylamino)ethanol, 2-(ethylamino)ethanol, 2-(propylamino)ethanol, diethanolamine, diisopropanolamine, N,N-dimethylethanolamine, N,N-diethylethanolamine, 2-(dibutylamino)ethanol, 3-dimethylamino-1-propanol, 3-diethylamino-1-propanol, 1-dimethylamino-2-propanol, 1-diethylamino-2-propanol, N-methyldiethanolamine, N-ethyldiethanolamine, 3-amino-1,2-propanediol, and mixtures thereof.

Molecular Precursor Preparation.

Preparing the molecular precursor typically comprises mixing the components (i)-(iv) by any conventional method. If one or more of the chalcogen sources is a liquid at room temperature or at the processing temperatures, the use of a separate solvent is optional. Otherwise, a solvent is used. In some embodiments, the molecular precursor is a solution; in other embodiments, the molecular precursor is a suspension or dispersion. Typically, the preparation is conducted under an inert atmosphere, taking precautions to protect the reaction mixtures from air and light.

In some embodiments, the molecular precursor is initially prepared at low temperatures and/or with slow additions, e.g., when larger amounts of reagents and/or low boiling point and/or highly reactive reagents such as CS₂ are utilized. In such cases, the ink is typically stirred at room temperature prior to heat processing. In some embodiments, the molecular precursor is prepared at about 20-100° C., e.g., when smaller amounts of reagents are used, when the reagents are solids or have high boiling points and/or when one or more of the solvents is a solid at room temperature, e.g., 2-aminopyridine or 3-aminopyridine. In some embodiments, all of the ink components are added together at room temperature, e.g., when smaller amounts of reagents are used. In some embodiments, elemental chalcogen is added last, following the mixing of all the other components for about half an hour at room temperature. In some embodiments, the components are added consecutively. For example, the indium source can be added slowly with mixing to a suspension of the copper source in the vehicle, or vice versa, followed by the addition of the chalcogen source(s).

Heat-Processing of the Molecular Precursor.

In some embodiments, the molecular precursor is heat-processed at a temperature of greater than about 90° C., 100° C., 110° C., 120° C., 130° C., 140° C., 150 C.°, 160° C., 170° C., 180° C. or, 190° C. before coating on the substrate. Suitable heating methods include conventional heating and microwave heating. In some embodiments, it has been found that this heat-processing step aids the formation of CIGS/Se. This optional heat-processing step is typically carried out under an inert atmosphere. The molecular precursor produced at this stage can be stored for extended periods (e.g., months) without any noticeable decrease in efficacy.

Mixtures of Molecular Precursors.

In some embodiments, two or more molecular precursors are prepared separately, with each molecular precursor comprising a complete set of reagents, e.g., each molecular precursor comprises at least a copper source, an indium source and a vehicle. The two or more molecular precursors can then be combined following mixing or following heat-processing. This method is especially useful for controlling stoichiometry and obtaining CIGS/Se of high purity, as prior to combining, separate films from each molecular precursor can be coated, annealed, and analyzed by XRD. The XRD results can then guide the selection of the type and amount of each molecular precursor to be combined. For example, a molecular precursor yielding an annealed film of CIGS/Se with traces of copper sulfide can be combined with a molecular precursor yielding an annealed film of CIGS/Se with traces of indium sulfide, to form a molecular precursor that yields an annealed film comprising only CIGS/Se, as determined by XRD. In some embodiments, a molecular precursor comprising a complete set of reagents is combined with molecular precursor(s) comprising a partial set of reagents. As an example, a molecular precursor containing only an indium source can be added in varying amounts to a molecular precursor comprising a complete set of reagents, and the stoichiometry can be optimized based upon the resulting device performances of annealed films of the mixtures.

### Plurality of Particles.

Molar Ratios of the Plurality of Particles.

In some embodiments, the molar ratio of Cu:(In+Ga) is about 1 in the plurality of particles. In some embodiments, the molar ratio of Cu:(In+Ga) is less than 1. In some embodiments, the molar ratio of total chalcogen to (Cu+In+Ga) is at least about 1 in the plurality of particles. As defined herein, the moles of total chalcogen and the moles of (Cu+In+Ga) are determined as defined above for the ink.

Particles.

The particles can be purchased or synthesized by known techniques such milling and sieving of bulk quantities of the material. In some embodiments, the particles have an average longest dimension of less than about 5 microns, 4 microns, 3 microns, 2 microns, 1.5 microns, 1.25 microns, 1.0 micron, or 0.75 micron.

Microparticles.

In some embodiments the particles comprise microparticles. The microparticles have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25, 50, 75, 100, 125, 150, 175, or 200 microns.

In embodiments in which in which the average longest dimension of the microparticles is less than the average thickness of the coated and/or annealed absorber layer, useful size ranges for microparticles are at least about 0.5 to about 10 microns, 0.6 to 5 microns, 0.6 to 3 microns, 0.6 to 2 microns, 0.6 to 1.5 microns, 0.6 to 1.2 microns, 0.8 to 2 microns, 1.0 to 3.0 microns, 1.0 to 2.0 microns, or 0.8 to 1.5 microns. In embodiments in which the average longest dimension of the microparticles is longer than the average thickness of the coated and/or annealed absorber layer, useful size ranges for microparticles are at least about 1 to about 200 microns, 2 to 200 microns, 2 to 100 microns, 3 to 100 microns, 2 to 50 microns, 2 to 25 microns, 2 to 20 microns, 2 to 15 microns, 2 to 10 microns, 2 to 5 microns, 4 to 50 microns, 4 to 25 microns, 4 to 20, 4 to 15, 4 to 10 microns, 6 to 50 microns, 6 to 25 microns, 6 to 20 microns, 6 to 15 microns, 6 to 10 microns, 10 to 50 microns, 10 to 25 microns, or 10 to 20 microns. The average thickness of the coated and/or annealed absorber layer can be determined by profilometry. The average longest dimension of the microparticles can be determined by electron microscopy.

Nanoparticles.

In some embodiments, the particles comprise nanoparticles. The nanoparticles can have an average longest dimension of less than about 500 nm, 400 nm, 300 nm, 250 nm, 200 nm, 150 nm, or 100 nm, as determined by electron microscopy. The nanoparticles can be purchased or synthesized by known techniques, such as: decomposition and reduction of metal salts and complexes; chemical vapor deposition; electrochemical deposition; use of gamma-, x-ray, laser or UV-irradiation; ultrasonic or microwave treatment; electron- or ion-beams; arc discharge; electric explosion of wires; or biosynthesis.

Capping Agent.

In some embodiments, the particles further comprise a capping agent. The capping agent can aid in the dispersion of particles and can also inhibit their interaction and agglomeration in the ink.

Suitable capping agents include:

(a) Organic molecules that contain functional groups such as N-, O-, S-, Se- or P-based functional groups;

(b) Lewis bases;

(c) Amines, thiols, selenols, phosphine oxides, phosphines, phosphinic acids, pyrrolidones, pyridines, carboxylates, phosphates, heteroaromatics, peptides, and alcohols;

(d) Alkyl amines, alkyl thiols, alkyl selenols, trialkylphosphine oxide, trialkylphosphines, alkylphosphonic acids, polyvinylpyrrolidone, polycarboxylates, polyphosphates, polyamines, pyridine, alkylpyridines, aminopyridines, peptides comprising cysteine and/or histidine residues, ethanolamines, citrates, thioglycolic acid, oleic acid, and polyethylene glycol;

(e) Inorganic chalcogenides, including metal chalcogenides, and zintl ions;

(f) S²⁻, Se²⁻, Se₂²⁻, Se₃²⁻, Se₄²⁻, Se₆²⁻, Te₂²⁻, Te₃²⁻, Te₄²⁻, In₂Se₄²⁻, and In₂Te₄²⁻, wherein the positively charged counterions can be alkali metal ions, ammonium, hydrazinium, or tetraalkylammonium;

(g) Degradable capping agents, including dichalcogenocarbamates, monochalcogenocarbamates, xanthates, trithiocarbonates, dichalcogenoimidodiphosphates, thiobiurets, dithiobiurets, chalcogenosemicarbazides, and tetrazoles. These capping agents can be degraded by thermal and/or chemical processes, such as acid- and base-catalyzed processes. Degradable capping agents include: dialkyl dithiocarbamates, dialkyl monothiocarbamates, dialkyl diselenocarbamates, dialkyl monoselenocarbamates, alkyl xanthates, alkyl trithiocarbonates, disulfidoimidodiphosphates, diselenoimidodiphosphates, tetraalkyl thiobiurets, tetraalkyl dithiobiurets, thiosemicarbazides, selenosemicarbazides, tetrazole, alkyl tetrazoles, amino-tetrazoles, thio-tetrazoles, and carboxylated tetrazoles. In some embodiments, Lewis bases (e.g., amines) can be added to nanoparticles stabilized by carbamate, xanthate, and trithiocarbonate capping agents to catalyze their removal from the nanoparticle;

(h) Molecular precursor complexes to copper chalcogenides, indium chalcogenides, and gallium chalcogenides. Ligands for these molecular precursor complexes include: thio groups, seleno groups, thiolates, selenolates, and thermally degradable ligands, as described above;

(i) Molecular precursor complexes to CuS/Se, Cu₂S/Se, InS/Se, In₂(S/Se)₃, GaS/Se, CuIn(S/Se)₂, and Cu(In/Ga)(S/Se)₂;

(j) The solvent in which the particle is formed, such as oleylamine; and

(k) Short-chain carboxylic acids, such as formic, acetic, or oxalic acids.

The Lewis base can be chosen such that it has a boiling temperature at ambient pressure that is greater than or equal to about 200° C., 150° C., 120° C., or 100° C., and/or can be selected from the group consisting of: organic amines, phosphine oxides, phosphines, thiols, and mixtures thereof. In some embodiments, the capping agent comprises a surfactant or a dispersant.

Volatile Capping Agents.

In some embodiments, the particles comprise a volatile capping agent. A capping agent is considered volatile if, instead of decomposing and introducing impurities when a composition or ink of nanoparticles is formed into a film, it evaporates during film deposition, drying or annealing. Volatile capping agents include those having a boiling point less than about 200° C., 150° C., 120° C., or 100° C. at ambient pressure. Suitable volatile capping agents include: ammonia, methyl amine, ethyl amine, propylamine, butylamine, tetramethylethylene diamine, acetonitrile, ethyl acetate, butanol, pyridine, ethanethiol, propanethiol, butanethiol, t-butylthiol, pentanethiol, hexanethiol, tetrahydrofuran, and diethyl ether. Suitable volatile capping agents can also include: amines, amidos, amides, nitriles, isonitriles, cyanates, isocyanates, thiocyanates, isothiocyanates, azides, thiocarbonyls, thiols, thiolates, sulfides, sulfinates, sulfonates, phosphates, phosphines, phosphites, hydroxyls, hydroxides, alcohols, alcoholates, phenols, phenolates, ethers, carbonyls, carboxylates, carboxylic acids, carboxylic acid anhydrides, glycidyls, and mixtures thereof.

Elemental Particles.

In some embodiments, the plurality of particles comprises elemental Cu-, In-, or Ga-containing particles. In some embodiments, the plurality of particles consists essentially of elemental Cu-, In-, or Ga-containing particles or mixtures thereof. In some embodiments, the plurality of particles consists essentially of elemental Cu- or In-containing particles or mixtures thereof. Suitable elemental Cu-, In-, or Ga-containing particles include: Cu particles, Cu—In alloy particles, Cu—Ga alloy particles, Cu—In—Ga alloy particles, In particles, In—Ga alloy particles, Ga particles; and mixtures thereof. In some embodiments, the elemental Cu-, In-, or Ga-containing particles are nanoparticles. The elemental Cu- or In-containing nanoparticles can be obtained from Sigma-Aldrich (St. Louis, Mo.), Nanostructured and Amorphous Materials, Inc. (Houston, Tex.), American Elements (Los Angeles, Calif.), Inframat Advanced Materials LLC (Manchester, Conn.), Xuzhou Jiechuang New Material Technology Co., Ltd. (Guangdong, China), Absolute Co. Ltd. (Volgograd, Russian Federation), MTI Corporation (Richmond, Va.), or Reade Advanced Materials (Providence, R.I.). Elemental Cu-, In-, or Ga-containing nanoparticles can also be synthesized according to known techniques, as described above. In some instances, the elemental Cu-, In-, or Ga-containing particles comprise a capping agent.

Binary or Ternary Chalcogenide Particles.

In some embodiments, the plurality of particles comprises binary or ternary Cu-, In-, or Ga-containing chalcogenide particles. In some embodiments, the plurality of particles consists essentially of binary or ternary Cu-, In-, or Ga-containing chalcogenide particles or mixtures thereof. In some embodiments, the plurality of particles consists essentially of elemental Cu-, In- or Ga-containing particles and binary or ternary Cu-, In-, or Ga-containing chalcogenide particles. In some embodiments, the plurality of particles consists essentially of binary or ternary Cu- or In-containing chalcogenide particles or mixtures thereof. In some embodiments, the chalcogenide is a sulfide or selenide. Suitable Cu-, In-, and Ga-containing binary or ternary chalcogenide particles include: Cu₂S/Se particles, CuS/Se particles, In₂(S,Se)₃ particles, InS/Se particles, Ga₂(S,Se)₃ particles, GaS/Se particles, (Ga,In)₂(S,Se)₃ particles, and mixtures thereof. In some instances, the binary or ternary Cu-, In-, or Ga-containing chalcogenide particles comprise a capping agent.

A particularly useful aqueous method for synthesizing mixtures of copper-, indium- and, optionally, gallium-containing chalcogenide nanoparticles comprises:
(a) providing a first aqueous solution comprising two or more metal salts and one or more ligands;
(b) optionally, adding a pH-modifying substance to form a second aqueous solution;
(c) combining the first or second aqueous solution with a chalcogen source to provide a reaction mixture; and
(d) agitating and optionally heating the reaction mixture to produce metal chalcogenide nanoparticles.

In one embodiment, the process further comprises separating the metal chalcogenide nanoparticles from the reaction mixture. In another embodiment, the process further comprises cleaning the surface of the nanoparticles. In another embodiment, the process further comprises reacting the surface of the nanoparticles with capping groups.

CIGS/Se Particles.

In some embodiments, the plurality of particles comprises CIGS/Se particles. In some embodiments, the plurality of particles consists essentially of CIGS/Se particles.

CIGS/Se Nanoparticles.

In some embodiments, the CIGS/Se particles comprise CIGS/Se nanoparticles. In some embodiments, the CIGS/Se particles consist essentially of CIGS/Se nanoparticles. The CIGS/Se nanoparticles can be synthesized by methods known in the art, as described above. CIGS/Se nanoparticles are available commercially from American Elements (Los Angeles, Calif.). A particularly useful aqueous method for synthesizing CIGS/Se nanoparticles comprises steps (a)-(d) as described above in the aqueous method for synthesizing mixtures of copper-, indium- and, optionally, gallium-containing chalcogenide nanoparticles, followed by steps (e) and (f):
(e) separating the metal chalcogenide nanoparticles from reaction by-products; and
(f) heating the metal chalcogenide nanoparticles to provide crystalline multinary-metal chalcogenide particles.

The annealing time can be used to control the CIGS/Se particle size, with particles ranging from nanoparticles to microparticles, as annealing time increases.

Capped Nanoparticles.

In some instances, the CIGS/Se nanoparticles comprise a capping agent. Capped CIGS and CIS nanoparticles are commercially available from Nanoco (Manchester, UK).

Coated binary, ternary, and quaternary chalcogenide nanoparticles, including CuS, CuSe, In₂S₃, In₂Se₃, Ga₂S₃, Ga₂Se₃, CuInS₂, CuInSe₂, CuGaS₂, CuGaSe₂, Cu(In,Ga)S₂ and Cu(In,Ga)Se₂ can be prepared from corresponding metal salts or complexes by reaction of the metal salt or complex with a source of sulfide or selenide in the presence of one or more stabilizing agents at a temperature between 0° C. and 500° C., or between 150° C. and 350° C. In some circumstances, the stabilizing agent also provides the coating. The chalcogenide nanoparticles can be isolated, for example, by precipitation by a non-solvent followed by centrifugation, and can be further purified by washing, or dissolving and re-precipitating. Suitable metal salts and complexes for this synthetic route include Cu(I), Cu(II), In(III), and Ga(III) halides, acetates, nitrates, and 2,4-pentanedionates. Suitable chalcogen sources include elemental sulfur, elemental selenium, Na₂S, Na₂Se, (NH₄)₂S, (NH₄)₂Se, thiourea, and thioacetamide. Suitable stabilizing agents include the capping agents to disclosed above. In particular, suitable stabilizing agents include: dodecylamine, tetradecyl amine, hexadecyl amine, octadecyl amine, oleylamine, trioctyl amine, trioctylphosphine oxide, other trialkylphosphine oxides, and trialkylphosphines.

Cu₂S nanoparticles can be synthesized by a solvothermal process, in which the metal salt is dissolved in deionized water. A long-chain alkyl thiol or selenol (e.g., 1-dodecanethiol or 1-dodecaneselenol) can serve as both the chalcogen source and as a dispersant for nanoparticles. Some additional ligands, including acetate and chloride, can be added in the form of an acid or a salt. The reaction is typically conducted at a temperature between 150° C. and 300° C. and at a pressure between 150 psig to 250 psig nitrogen. After cooling, the product can be isolated from the non-aqueous phase, for example, by precipitation using a non-solvent and filtration.

The chalcogenide nanoparticles can also be synthesized by an alternative solvothermal process in which the corresponding metal salt is dispersed along with thioacetamide, thiourea, selenoacetamide, selenourea or other source of sulfide or selenide ions and an organic stabilizing agent (e.g., a long-chain alkyl thiol or a long-chain alkyl amine) in a suitable solvent at a temperature between 150° C. and 300° C. The reaction is typically conducted at a pressure between 150 psig nitrogen and 250 psig nitrogen. Suitable metal salts for this synthetic route include Cu(I), Cu(II), In(III), and Ga(III) halides, acetates, nitrates, and 2,4-pentanedionates.

The resultant chalcogenide nanoparticles obtained from any of the three routes are coated with the organic stabilizing agent(s), as can be determined by secondary ion mass spectrometry and nuclear magnetic resonance spectroscopy. The structure of the inorganic crystalline core of the coated nanoparticles can be determined by X-ray diffraction (XRD) and transmission electron microscopy (TEM) techniques.

CIGS/Se Microparticles.

In some embodiments, the CIGS/Se particles comprise CIGS/Se microparticles. In some embodiments, the CIGS/Se particles consist essentially of CIGS/Se microparticles. The CIGS/Se microparticles can be synthesized by methods known in the art. A useful method for the synthesis of CISe microparticles involves reacting Cu—In alloy and Se molten fluxes. The crystal size of the materials can be controlled by the temperature and duration of the recrystallization process and by the chemical nature of the flux. The aqueous method described above is another particularly useful method for synthesizing CIGS/Se microparticles. In some instances, the microparticles synthesized via these methods are larger than desired. In such cases, the CIGS/Se microparticles can be milled or sieved using standard techniques to achieve the desired particle size.

In some instances, the CIGS/Se microparticles comprise a capping agent. The coated CIGS/Se microparticles can be synthesized by standard techniques known in the art, such as mixing the microparticle with a liquid capping agent, optionally with heating, and then washing the coated particles to remove excess capping agent. CIGS/Se microparticles capped with CIGS/Se molecular precursors can be synthesized by mixing CIGS/Se microparticles with the CIGS/Se molecular precursor ink described above. In some embodiments, the mixture is heat-processed at a temperature of greater than about 50° C., 75° C., 90° C., 100° C., 110° C., 120° C., 130° C., 140° C., 150 C.°, 160° C., 170° C., 180° C. or 190° C. Suitable heating methods include conventional heating and microwave heating. In some embodiments, the CIGS/Se microparticles are mixed with a molecular precursor ink wherein solvent(s) comprise less than about 90 wt %, 80 wt %, 70 wt %, 60 wt %, or 50 wt % of the ink, based upon the total weight of the ink. Following mixing and optional heating, the CIGS/Se microparticles are washed with solvent to remove excess molecular precursor. Suitable solvents for washing can be selected from the above list of solvents for the molecular precursor.

### Additional Ink Components

In addition to the molecular precursor and the plurality of particles, in various embodiments the ink further comprises additive(s), an elemental chalcogen, or mixtures thereof.

Additives.

In some embodiments, the ink further comprises one or more additives. Suitable additives include dispersants, surfactants, polymers, binders, ligands, capping agents, defoamers, thickening agents, corrosion inhibitors, plasticizers, thixotropic agents, viscosity modifiers, and dopants. In some embodiments, additives are selected from the group consisting of capping agents, dopants, polymers, and surfactants. In some embodiments, the ink comprises up to about 10 wt %, 7.5 wt %, 5 wt %, 2.5 wt % or 1 wt % additives, based upon the total weight of the ink. Suitable capping agents comprise the capping agents, including volatile capping agents, described above.

Dopants.

Suitable dopants include sodium and alkali-containing compounds. In some embodiments, the alkali-containing compounds are selected from the group consisting of: alkali compounds comprising N-, O-, C-, S-, or Se-based organic ligands, alkali sulfides, alkali selenides, and mixtures thereof. In other embodiments, the dopant comprises an alkali-containing compound selected from the group consisting of: alkali-compounds comprising amidos; alkoxides; acetylacetonates; carboxylates; hydrocarbyls; O-, N-, S-, Se-, halogen-, or tri(hydrocarbyl)silyl-substituted hydrocarbyls; thiolates and selenolates; thio-, seleno-, and dithiocarboxylates; dithio-, diseleno-, and thioselenocarbamates; and dithioxanthogenates. Other suitable dopants include antimony chalcogenides selected from the group consisting of antimony sulfide and antimony selenide.

Polymers and Surfactants.

Suitable polymeric additives include vinylpyrrolidone-vinylacetate copolymers and (meth)acrylate copolymers, including PVP/VA E-535 (International Specialty Products), and Elvacite® 2028 binder and Elvacite® 2008 binder (Lucite International, Inc.). In some embodiments, polymers can function as binders or dispersants.

Suitable surfactants comprise siloxy-, fluoryl-, alkyl-, alkynyl-, and ammonium-substituted surfactants. These include, for example, Byk® surfactants (Byk Chemie), Zonyl® surfactants (DuPont), Triton® surfactants (Dow), Surfynol® surfactants (Air Products), Dynol® surfactants (Air Products), and Tego® surfactants (Evonik Industries AG). In certain embodiments, surfactants function as coating aids, capping agents, or dispersants.

In some embodiments, the ink comprises one or more binders or surfactants selected from the group consisting of: decomposable binders; decomposable surfactants; cleavable surfactants; surfactants with a boiling point less than about 250° C.; and mixtures thereof. Suitable decomposable binders include: homo- and co-polymers of polyethers; homo- and co-polymers of polylactides; homo- and co-polymers of polycarbonates including, for example, Novomer PPC (Novomer, Inc.); homo- and co-polymers of poly[3-hydroxybutyric acid]; homo- and co-polymers of polymethacrylates; and mixtures thereof. A suitable low-boiling surfactant is Surfynol® 61 surfactant from Air Products. Cleavable surfactants useful herein as capping agents include Diels-Alder adducts, thiirane oxides, sulfones, acetals, ketals, carbonates, and ortho esters. Suitable cleavable surfactants include: alkyl-substituted Diels Alder adducts, Diels Alder adducts of furans; thiirane oxide; alkyl thiirane oxides; aryl thiirane oxides; piperylene sulfone, butadiene sulfone, isoprene sulfone, 2,5-dihydro-3-thiophene carboxylic acid-1,1-dioxide-alkyl esters, alkyl acetals, alkyl ketals, alkyl 1,3-dioxolanes, alkyl 1,3-dioxanes, hydroxylacetals, alkyl glucosides, ether acetals, polyoxyethylene acetals, alkyl carbonates, ether carbonates, polyoxyethylene carbonates, ortho esters of formates, alkyl ortho esters, ether ortho esters, and polyoxyethylene ortho esters.

Elemental Chalcogen.

In some embodiments, the ink comprises an elemental chalcogen selected from the group consisting of sulfur, selenium, and mixtures thereof. Useful forms of sulfur and selenium include powders that can be obtained from Sigma-Aldrich (St. Louis, Mo.) and Alfa Aesar (Ward Hill, Mass.). In some embodiments, the chalcogen powder is soluble in the ink vehicle. If the chalcogen is not soluble in the vehicle, its particle size can be 1 nm to 200 microns. In some embodiments, the particles have an average longest dimension of less than about 100 microns, 50 microns, 25 microns, 10 microns, 5 microns, 4 microns, 3 microns, 2 microns, 1.5 microns, 1.25 microns, 1.0 micron, 0.75 micron, 0.5 micron, 0.25 micron, or 0.1 micron. Preferably, the chalcogen particles are smaller than the thickness of the film that is to be formed. The chalcogen particles can be formed by ball milling, evaporation-condensation, melting and spraying (“atomization”) to form droplets, or emulsification to form colloids.

Ink Preparation.

Typically, ink preparation is conducted under an inert atmosphere, taking precautions to protect the reaction mixtures from air and light. Preparing an ink comprises mixing a molecular precursor with a plurality of particles by any conventional method. Typically, the molecular precursor portion of the ink is prepared as described above with components (i)-(iv) added and mixed, often with heat processing, prior to the addition of the particles. Then the plurality of particles is added to the molecular precursor at room temperature, followed by mixing, and, optionally, heat treatment. Depending on the relative amounts of the molecular precursor and plurality of particles, it can be necessary to add solvent to the ink to adjust the viscosity. The solvent can be added before or after heat treatment. In some embodiments, suitable solvents are as described above for the preparation of the molecular precursor. In some embodiments, the wt % of the plurality of particles in the ink, based upon the weight of the final ink, ranges from about 95 to about 5 wt %, 90 to 10 wt %, 80 to 20 wt %, 70 to 30 wt %, or 60 to 40 wt %. In some embodiments, particularly those wherein the plurality of particles comprises microparticles, the wt % of the particles in the ink, based upon the weight of the final ink, is less than about 90 wt %, 80 wt %, 70 wt %, 60 wt %, 50 wt %, 40 wt %, 30 wt %, 20 wt %, 10 wt %, or 5 wt %.

Typically, the plurality of particles is added as a dry solid to the molecular precursor. In some embodiments, the plurality of particles can be added as a dispersion in a second vehicle to the molecular precursor. In some embodiments, the second vehicle is selected from the group consisting of: fluids and low melting solids, wherein the melting point of the low-melting solid is less than about 100° C., 90° C., 80° C., 70° C., 60° C., 50° C., 40° C., or 30° C. In some embodiments, the second vehicle comprises solvents. The solvents can be selected from the lists above. Suitable solvents include aromatics, heteroaromatics, alkanes, chlorinated alkanes, ketones, esters, nitriles, amides, amines, thiols, pyrrolidinones, ethers, thioethers, alcohols, and mixtures thereof. In some embodiments, the wt % of the second vehicle in the dispersion of particles that is added to the molecular precursor is about 95 to about 5 wt %, 90 to 10 wt %, 80 to 20 wt %, 70 to 30 wt %, or 60 to 40 wt %, based upon the total weight of the dispersion. In some embodiments, the second vehicle can function as a dispersant or capping agent, as well as being the carrier vehicle for the particles. Solvent-based second vehicles that are particularly useful as capping agents comprise heteroaromatics, amines, or thiols.

In some embodiments, particularly those in which the average longest dimension of the microparticles is longer than the desired average thickness of the coated and/or annealed absorber layer, the ink is prepared on a substrate. Suitable substrates for this purpose are as described below. For example, the molecular precursor can be deposited on the substrate, with suitable deposition techniques as described below. Then the plurality of particles can be added to the molecular precursor by techniques such as sprinkling the plurality of the particles onto the deposited molecular precursor.

Heat-Processing of the Ink.

In some embodiments, the ink is heat-processed at a temperature of greater than about 90° C., 100° C., 110° C., 120° C., 130° C., 140° C., 150 C.°, 160° C., 170° C., 180° C., or 190° C. before coating on the substrate. Suitable heating methods include conventional heating and microwave heating. In some embodiments, it has been found that this heat-processing step aids the dispersion of the plurality of particles within the molecular precursor. Films made from heat-processed inks typically have smooth surfaces, an even distribution of particles within the film as observed by SEM, and improved performance in photovoltaic devices as compared to inks of the same composition that were not heat processed. This optional heat-processing step is typically carried out under an inert atmosphere. The ink produced at this stage can be stored for months without any noticeable decrease in efficacy.

Mixtures of Inks.

As described above for the mixture of molecular precursors, in some embodiments two or more inks are prepared separately, with each ink comprising a molecular precursor and a plurality of particles. The two or more inks can then be combined following mixing or following heat-processing. This method is especially useful for controlling stoichiometry and obtaining CIGS/Se of high purity. In other embodiments, an ink comprising a complete set of reagents, e.g., a molecular precursor to CIGS/Se and a plurality of particles, is combined with ink(s) comprising a partial set of reagents. As an example, an ink containing only an indium source can be added in varying amounts to an ink comprising a complete set of reagents, and the stoichiometry can be optimized based upon the resulting device performances of annealed films of the mixtures.

### Coated Substrate

Another aspect of this invention is a process comprising disposing an ink onto a substrate to form a coated substrate, wherein the ink comprises:

a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof; and
   b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

Another aspect of this invention is a coated substrate comprising:

A) a substrate; and
B) at least one layer disposed on the substrate comprising:

a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof; and
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and

b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

Descriptions and preferences regarding the molecular precursor components (i)-(iii), the plurality of particles, the optional chalcogen compounds, and the molar ratios are the same as described above for the molecular precursor and the ink.

In some embodiments, the copper source is selected from the group consisting of copper complexes of nitrogen-, oxygen-, carbon-, sulfur-, or selenium-based organic ligands and mixtures thereof.

In some embodiments, the copper source is selected from the group consisting of copper sulfides, copper selenides, and mixtures thereof.

In some embodiments, the indium source is selected from the group consisting of indium complexes of nitrogen-, oxygen-, carbon-, sulfur-, or selenium-based organic ligands and mixtures thereof.

In some embodiments, the indium source is selected from the group consisting of indium sulfides, indium selenides, and mixtures thereof.

In some embodiments, the copper source is selected from the group consisting of copper complexes of nitrogen-, oxygen-, carbon-, sulfur-, or selenium-based organic ligands and mixtures thereof and the indium source is selected from the group consisting of indium complexes of nitrogen-, oxygen-, carbon-, sulfur-, or selenium-based organic ligands and mixtures thereof.

In some embodiments, the copper source is selected from the group consisting of copper complexes of nitrogen-, oxygen-, carbon-, sulfur-, or selenium-based organic ligands and mixtures thereof and the indium source is selected from the group consisting of indium sulfides, indium selenides, and mixtures thereof.

In some embodiments, the copper source is selected from the group consisting of copper sulfides, copper selenides, and mixtures thereof and the indium source is selected from the group consisting of indium complexes of nitrogen-, oxygen-, carbon-, sulfur-, or selenium-based organic ligands and mixtures thereof.

In some embodiments, the molecular precursor consists essentially of components (i)-(ii). In some embodiments, the gallium source is present and the molecular precursor consists essentially of components (i)-(iii).

In some embodiments, the molecular precursor further comprises a chalcogen compound. In some embodiments, the copper source is selected from the group consisting of copper complexes of nitrogen-, oxygen-, carbon-, sulfur-, or selenium-based organic ligands and mixtures thereof, or the indium source is selected from the group consisting of indium complexes of nitrogen-, oxygen-, carbon-, sulfur-, or selenium-based organic ligands and mixtures thereof, and the molecular precursor further comprises a chalcogen compound. In some embodiments, the copper or indium source comprises a nitrogen-, oxygen-, or carbon-based organic ligand, and the molecular precursor further comprises a chalcogen compound. In some embodiments, the copper and indium sources comprise a nitrogen-, oxygen-, or carbon-based organic ligand, and the molecular precursor further comprises a chalcogen compound.

Another aspect of this invention is a coated substrate comprising:

(a) a substrate; and
(b) at least one layer disposed on the substrate comprising:
i) an inorganic matrix; and
ii) CIGS/Se microparticles characterized by an average longest dimension of 0.5-200 microns, wherein the microparticles are embedded in the inorganic matrix.

Inorganic Matrix.

In the coated substrate, the inorganic matrix comprises inorganic semiconductors, precursors to inorganic semiconductors, inorganic insulators, precursors to inorganic insulators, or mixtures thereof. In some embodiments, the matrix comprises at least 50 wt %, 60 wt %, 70 wt %, 80 wt %, 90 wt %, 95 wt %, or 98 wt %, or consists essentially of inorganic semiconductors, precursors to inorganic semiconductors, inorganic insulators, precursors to inorganic insulators, or mixtures thereof. Materials designated as inorganic matrixes can also contain small amounts of other materials, including dopants, such as sodium, and organic materials. Suitable inorganic matrixes comprise Group IV elemental or compound semiconductors; Group III-V, II-VI, I-VII, IV-VI, V-VI, or II-V semiconductors; oxides, sulfides, nitrides, phosphides, selenides, carbides, antimonides, arsenides, selenides, tellurides, or silicides; precursors thereof; or mixtures thereof. Examples of suitable inorganic matrixes include Cu(In,Ga)(S,Se)₂, Cu₂ZnSn(S,Se)₄, and SiO₂.

The inorganic matrix is used in combination with microparticles of chalcogenide semiconductor to build a coated film. In some embodiments, the bulk of the functionality comes from the microparticles, and the inorganic matrix plays a role in layer formation and enhancement of the layer performance. The longest dimension of the microparticles can be greater than the average thickness of the inorganic matrix and, in some instances, can span the coating thickness. The longest dimension of the microparticles can be less than or equivalent to the coating thickness, resulting in a film with completely or partially embedded microparticles. The microparticles and inorganic matrix can comprise different materials, can vary in some aspects of similar compositions, or can consist of essentially the same composition.

Preparation of the Inorganic Matrix.

Inorganic matrixes can be prepared by standard methods known in the art for preparing inorganic semiconductors, inorganic insulators, and precursors thereof, and can be combined with microparticles by procedures analogous to those described above for combining the molecular precursor with the plurality of particles. For example, an inorganic matrix comprising SiO₂ or precursors thereof can be prepared from sol gel precursors to SiO₂. Alternatively, an inorganic matrix comprising Cu(In,Ga)(S,Se)₂ or precursors thereof can be prepared as described above using molecular precursors and/or a plurality of particles selected from the group consisting of: CIGS/Se particles; elemental Cu-, In-, or Ga-containing particles; binary or ternary Cu-, In-, or Ga-containing chalcogenide particles; and mixtures thereof. Also, an inorganic matrix comprising Cu₂ZnSn(S,Se)₄ or precursors thereof can be prepared using molecular precursors to CZTS/Se and/or a plurality of particles selected from the group consisting of: CZTS/Se particles; elemental Cu-, Zn-, or Sn-containing particles; binary or ternary Cu-, Zn-, or Sn-containing chalcogenide particles; and mixtures thereof. In some embodiments, the plurality of particles comprises or consists essentially of nanoparticles. Molecular precursors to CZTS/Se can be prepared from:
i) a copper source selected from the group consisting of copper complexes of N-, O-, C-, S-, or Se-based organic ligands, copper sulfides, copper selenides, and mixtures thereof;
ii) a tin source selected from the group consisting of tin complexes of N-, O-, C-, S-, or Se-based organic ligands, tin hydrides, tin sulfides, tin selenides, and mixtures thereof;
iii) a zinc source selected from the group consisting of zinc complexes of N-, O-, C-, S-, or Se-based organic ligands, zinc sulfides, zinc selenides, and mixtures thereof; and
iv) a vehicle, comprising a liquid chalcogen compound, a liquid tin source, a solvent, or a mixture thereof.

The nitrogen-, oxygen-, carbon-, sulfur-, or selenium-based organic ligands can be selected from the lists given above. In some embodiments, the molecular precursor to Cu₂ZnSn(S,Se)₄ further comprises a chalcogen compound. The chalcogen compound can be selected from the lists given above.

Substrate.

The substrate can be rigid or flexible. In one embodiment, the substrate comprises: (i) a base; and (ii) optionally, an electrically conductive coating on the base. The base material is selected from the group consisting of glass, metals, ceramics, and polymeric films. Suitable base materials include metal foils, plastics, polymers, metalized plastics, glass, solar glass, low-iron glass, green glass, soda-lime glass, metalized glass, steel, stainless steel, aluminum, ceramics, metal plates, metalized ceramic plates, and metalized polymer plates. In some embodiments, the base material comprises a filled polymer (e.g., a polyimide and an inorganic filler). In some embodiments, the base material comprises a metal (e.g., stainless steel) coated with a thin insulating layer (e.g., alumina).

Suitable electrically conductive coatings include metal conductors, transparent conducting oxides, and organic conductors. Of particular interest are substrates of molybdenum-coated soda-lime glass, molybdenum-coated polyimide films, and molybdenum-coated polyimide films further comprising a thin layer of a sodium compound (e.g., NaF, Na₂S, or Na₂Se).

Ink Deposition.

The ink is disposed on a substrate to provide a coated substrate by solution-based coating or printing techniques, including spin-coating, spray-coating, dip-coating, rod-coating, drop-cast coating, roller-coating, slot-die coating, draw-down coating, ink-jet printing, contact printing, gravure printing, flexographic printing, and screen printing. The coating can be dried by evaporation, by applying vacuum, by heating, by blowing, or by combinations thereof. In some embodiments, the substrate and disposed ink are heated at a temperature from 80-350° C., 100-300° C., 120-250° C., 150-190° C., or 120-170° C. to remove at least a portion of the solvent, and volatile by-products, such as volatile capping agents. The drying step can be a separate, distinct step, or can occur as the substrate and precursor ink are heated in an annealing step.

Coated Substrate.

In some embodiments, the molar ratio of Cu:(In+Ga) in the at least one layer of the coated substrate is about 1. In some embodiments, the molar ratio of Cu:(In+Ga) in the at least one layer is less than 1. In some embodiments, the molar ratio of total chalcogen to (Cu+In+Ga) in the at least one layer is at least about 1.

Coated Substrate Comprising Nanoparticles.

In some embodiments, the plurality of particles in the at least one layer of the coated substrate comprises or consists essentially of nanoparticles having an average longest dimension of less than about 500 nm, 400 nm, 300 nm, 250 nm, 200 nm, 150 nm, or 100 nm, as determined by electron microscopy. As measured by profilometry, Ra (average roughness) is the arithmetic average deviation of roughness. In some embodiments, the plurality of particles of the coated substrate consists essentially of nanoparticles, and the Ra of the at least one layer is less than about 1 micron, 0.9 microns, 0.8 microns, 0.7 microns, 0.6 microns, 0.5 microns, 0.4 microns or 0.3 microns, as measured by profilometry.

Coated Substrate Comprising CIGS/Se Microparticles.

In some embodiments, the particles of the coated substrate comprise or consist essentially of CIGS/Se microparticles. In some embodiments, the plurality of particles of the at least one layer of the coated substrate comprises or consists essentially of CIGS/Se microparticles, and the at least one layer comprises CIGS/Se microparticles embedded in an inorganic matrix. In some embodiments, the matrix comprises inorganic particles and the average longest dimension of the microparticles is longer the average longest dimension of the inorganic particles. In some embodiments, the inorganic particles comprise CIGS/Se particles; elemental Cu-, In-, or Ga-containing particles; binary or ternary Cu-, In-, or Ga-containing particles; or mixtures thereof. In some embodiments, the matrix comprises or consists essentially of CIGS/Se or CIGS/Se particles.

The particle sizes can be determined by techniques such as electron microscopy. In some embodiments, the CIGS/Se microparticles of the coated substrate have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25 or 50 microns, and the inorganic particles of the coated substrate have an average longest dimension of less than about 10, 7.5, 5.0, 4.0, 3.0, 2.0, 1.5, 1.0, 0.75, 0.5, 0.4, 0.3, 0.2, or 0.1 microns. In some embodiments, the inorganic particles comprise or consist essentially of nanoparticles.

In some embodiments, the absolute value of the difference between the average longest dimension of the CIGS/Se microparticles of the coated substrate and the average thickness of the at least one layer is at least about 0.1, 0.2, 0.3, 0.4, 0.5, 0.75, 1.0, 1.5, 2.0, 2.5, 3.0, 5.0, 10.0, 15.0, 20.0 or 25.0 microns. In some embodiments, the average longest dimension of the CIGS/Se microparticles of the coated substrate is less than the average thickness of the at least one layer. In some embodiments, the average longest dimension of the CIGS/Se microparticles of the coated substrate is less than the thickness of the at least one layer, and the Ra of the at least one layer is less than about 1 micron, 0.9 microns, 0.8 microns, 0.7 microns, 0.6 microns, 0.5 microns, 0.4 microns or 0.3 microns, as measured by profilometry. In some embodiments, the average longest dimension of the CIGS/Se microparticles of the coated substrate is greater than the average thickness of the at least one layer.

Annealing.

In some embodiments, the coated substrate is heated at about 100-800° C., 200-800° C., 250-800° C., 300-800° C., 350-800° C., 400-650° C., 450-600° C., 450-550° C., 450-525° C., 100-700° C., 200-650° C., 300-600° C., 350-575° C., or 350-525° C. In some embodiments, the coated substrate is heated for a time in the range of about 1 min to about 48 h; 1 min to about 30 min; 10 min to about 10 h; 15 min to about 5 h; 20 min to about 3 h; or, 30 min to about 2 h. Typically, the annealing comprises thermal processing, rapid thermal processing (RTP), rapid thermal annealing (RTA), pulsed thermal processing (PTP), laser beam exposure, heating via IR lamps, electron beam exposure, pulsed electron beam processing, heating via microwave irradiation, or combinations thereof. Herein, RTP refers to a technology that can be used in place of standard furnaces and involves single-wafer processing, and fast heating and cooling rates. RTA is a subset of RTP, and consists of unique heat treatments for different effects, including activation of dopants, changing substrate interfaces, densifying and changing states of films, repairing damage, and moving dopants. Rapid thermal anneals are performed using either lamp-based heating, a hot chuck, or a hot plate. PTP involves thermally annealing structures at extremely high power densities for periods of very short duration, resulting, for example, in defect reduction. Similarly, pulsed electron beam processing uses a pulsed high energy electron beam with short pulse duration. Pulsed processing is useful for processing thin films on temperature-sensitive substrates. The duration of the pulse is so short that little energy is transferred to the substrate, leaving it undamaged.

In some embodiments, the annealing is carried out under an atmosphere comprising: an inert gas (nitrogen or a Group VIIIA gas, particularly argon); optionally hydrogen; and optionally, a chalcogen source such as selenium vapor, sulfur vapor, hydrogen sulfide, hydrogen selenide, diethyl selenide, or mixtures thereof. The annealing step can be carried out under an atmosphere comprising an inert gas, provided that the molar ratio of total chalcogen to (Cu+In+Ga) in the coating is greater than about 1. If the molar ratio of total chalcogen to (Cu+In+Ga) is less than about 1, the annealing step is carried out in an atmosphere comprising an inert gas and a chalcogen source. In some embodiments, at least a portion of the chalcogen present in the coating (e.g., S) can be exchanged (e.g., S can be replaced by Se) by conducting the annealing step in the presence of a different chalcogen (e.g., Se). In some embodiments, annealings are conducted under a combination of atmospheres. For example, a first annealing is carried out under an inert atmosphere and a second annealing is carried out in an atmosphere comprising an inert gas and a chalcogen source as described above or vice versa. In some embodiments, the annealing is conducted with slow heating and/or cooling steps, e.g., temperature ramps and/or declines of less than about 15° C./min, 10° C./min, 5° C./min, 2° C./min, or 1° C./min. In other embodiments, the annealing is conducted with rapid heating and/or cooling steps, e.g., temperature ramps and/or declines of greater than about 15° C. per min, 20° C. per min, 30° C. per min, 45° C. per min, or 60° C. per min.

Additional Layers.

In some embodiments, the coated substrate further comprises one or more additional layers. These one or more layers can be of the same composition as the at least one layer or can differ in composition. In some embodiments, particularly suitable additional layers comprise CIGS/Se precursors selected from the group consisting of: CIGS/Se molecular precursors, CIGS/Se nanoparticles, elemental Cu-, In- or Ga-containing nanoparticles; binary or ternary Cu-, In- or Ga-containing chalcogenide nanoparticles; and mixtures thereof. In some embodiments, the one or more additional layers are coated on top of the at least one layer. This layered structure is particularly useful when the at least one layer contains microparticles, as the top-coated additional layers can serve to planarize the surface of the at least one layer or fill in voids in the at least one layer. In some embodiments, the one or more additional layers are coated prior to coating the at least one layer. This layered structure is also particularly useful when the at least one layer contains microparticles, as the one or more additional layers serve as underlayers that can improve the adhesion of the at least one layer and prevent any shorts that might result from voids in the at least one layer. In some embodiments, the additional layers are coated both prior to and subsequent to the coating of the at least one layer.

In some embodiments, a soft-bake step and/or annealing step occurs between coating the at least one layer and the one or more additional layers.

### Films.

Another aspect of this invention is a film comprising:

a) an inorganic matrix; and
b) CIGS/Se microparticles characterized by an average longest dimension of 0.5-200 microns, wherein the microparticles are embedded in the inorganic matrix.

CIGS/Se Composition.

An annealed film comprising CIGS/Se is produced by the above annealing processes. In some embodiments, the coherent domain size of the CIGS/Se film is greater than about 30 nm, 40 nm, 50 nm, 60 nm, 70 nm, 80 nm, 90 nm, or 100 nm, as determined by XRD. In some embodiments, the molar ratio of Cu:(In+Ga) in the film is about 1. In some embodiments, the molar ratio of Cu:(In+Ga) in the film is less than 1.

In some embodiments, the annealed films are produced from coated substrates wherein the particles of the coated substrate comprise or consist essentially of CIGS/Se microparticles, as described above. In some embodiments, the annealed film comprises CIGS/Se microparticles embedded in an inorganic matrix. In some embodiments, the inorganic matrix comprises or consists essentially of CIGS/Se or CIGS/Se particles.

The composition and planar grain sizes of the annealed film, as determined by electron microscopy and EDX measurements, can vary depending on the ink composition, processing, and annealing conditions. According to these methods, in some embodiments, the microparticles are indistiguishable from the grains of the inorganic matrix in terms of size and/or composition, and in other embodiments, the microparticles are distinguishable from the grains of the inorganic matrix in terms of size and/or composition. In some embodiments, the planar grain size of the matrix is at least about 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 2.5, 3.0, 3.5, 4.0, 4.5, 5.0, 7.5, 10, 15, 20, 25 or 50 microns. In some embodiments, the CIGS/Se microparticles have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 3.5, 4.0, 5.0, 7.5, 10, 15, 20, 25 or 50 microns. In some embodiments, the absolute value of the difference between the average longest dimension of the CIGS/Se microparticles and the planar grain size of the inorganic matrix is at least about 0.1, 0.2, 0.3, 0.4, 0.5, 0.75, 1.0, 1.5, 2.0, 2.5, 3.0, 5.0, 7.5, 10.0, 15.0, 20.0 or 25.0 microns. In various embodiments, the average longest dimension of the microparticles is less than, greater than, or equivalent to the planar grain size of the inorganic matrix.

In various embodiments in which both the CIGS/Se microparticles and the inorganic matrix consist essentially of CIGS/Se, there can be differences in the composition of the CIGS/Se microparticles and the inorganic matrix. The differences can be due to differences in one or more of: (a) the fraction of chalcogenide present as sulfur or selenium in the CIGS/Se, (b) the molar ratio of Cu to (In+Ga); (c) the molar ratio of In to Ga; (d) the molar ratio of total chalcogen to (Cu+In) or of total chalcogen to (Cu+In+Ga); (e) the amount and type of dopants; and (f) the amount and type of trace impurities. In some embodiments, the composition of the matrix is given by Cu(InᵣGa₁₋ᵣ)(SₘSe₂₋ₘ), where 0≦m≦2 and 0<r≦1, and the composition of the microparticles is given by Cu(InₛGa₁₋ₛ)(SₙSe₂₋ₙ), where 0≦n≦2 and 0<s≦1, and the absolute value of the difference between m and n is at least about 0.1, 0.2, 0.3, 0.4, 0.5, 0.75, 1, 0, 1.25, 1.5, 1.75, or 2.0; or the absolute value of the difference between r and s is at least about 0.05, 0.1, 0.2, 0.3, 0.4, 0.5, 0.75 or 1.0. In some embodiments, the molar ratio of Cu to (In+Ga) of the CIGS/Se microparticles is MR1 and the molar ratio of Cu to (In+Ga) of the CIGS/Se matrix is MR2, and the absolute value of the difference between MR1 and MR2 is at least about 0.1, 0.2, 0.3, 0.4, or 0.5. In some embodiments, the molar ratio of In to Ga of the CIGS/Se microparticles is MR3 and the molar ratio of In to Ga of the CIGS/Se matrix is MR4, and the difference between MR3 and MR4 is at least about 0.1, 0.2, 0.3, 0.4, or 0.5. In some embodiments, the molar ratio of total chalcogen to (Cu+In+Ga) of the CIGS/Se microparticles is MR5 and the molar ratio of total chalcogen to (Cu+In+Ga) of the CIGS/Se matrix is MR6, and the absolute value of the difference between MR5 and MR6 is at least about 0.1, 0.2, 0.3, 0.4, or 0.5. In some embodiments, a dopant is present in the film, and the absolute value of the difference between the wt % of the dopant in the CIGS/Se microparticles and in the inorganic matrix is at least about 0.05, 0.1, 0.2, 0.3, 0.4, 0.5, 0.75, or 1 wt %. In some embodiments, dopants comprise an alkali metal (e.g., Na) or Sb. In some embodiments, a trace impurity is present in the film, and the absolute value of the difference between the wt % of the impurity in the CIGS/Se microparticles and in the inorganic matrix is at least about 0.05, 0.1, 0.2, 0.3, 0.4, 0.5, 0.75, or 1 wt %. In some embodiments, trace impurities comprise one or more of F, Cl, Br, I, C, O, Ca, Al, W, Fe, Cr, and N.

In some embodiments, the absolute value of the difference between the average longest dimension of the CIGS/Se microparticles and the thickness of the annealed film is at least about 0.1, 0.2, 0.3, 0.4, 0.5, 0.75, 1.0, 1.5, 2.0, 2.5, 3.0, 5.0, 10.0, 15.0, 20.0 or 25.0 microns. In some embodiments, the average longest dimension of the CIGS/Se microparticles is less than the average thickness of annealed film. In some embodiments, the average longest dimension of the CIGS/Se microparticles is less than the average thickness of the annealed film, and the Ra of the annealed film is less than about 1 micron, 0.9 micron, 0.8 micron, 0.7 micron, 0.6 micron, 0.5 micron, 0.4 micron, 0.3 micron, 0.2 micron, 0.1 micron, 0.075 micron, or 0.05 micron, as measured by profilometry. In some embodiments, the average longest dimension of the CIGS/Se microparticles is greater than the average thickness of the annealed film.

It has been found that CIGS/Se can be formed in high yield during the annealing step, as determined by XRD or x-ray absorption spectroscopy (XAS). In some embodiments, the annealed film consists essentially of CIGS/Se, according to XRD analysis or XAS. In some embodiments, at least about 90%, 95%, 96%, 97%, 98%, 99% or 100% of the copper is present as CIGS/Se in the annealed film, as determined by XAS. This film can be further characterized by: at least about 80%, 85%, 90%, 95%, 96%, 97%, 98%, 99% or 100% of the indium is present as CIGS/Se, as determined by XAS.

Coating and Film Thickness.

By varying the ink concentration and/or coating technique and temperature, layers of varying thickness can be coated in a single coating step. In some embodiments, the coating thickness can be increased by repeating the coating and drying steps. These multiple coatings can be conducted with the same ink or with different inks. As described above, wherein two or more inks are mixed, the coating of multiple layers with different inks can be used to fine-tune stoichiometry and purity of the CIGS/Se films. It can also be used to tune the absorption of the film, e.g., by creating films with gradient CIGS/Se compositions. Soft-bake and annealing steps can be carried out between the coating of multiple layers. In these instances, the coating of multiple layers with different inks can be used to create gradient layers, such as layers that vary in the S/Se ratio. The coating of multiple layers can also be used to fill in voids in the at least one layer and planarize or create an underlayer to the at least one layer, as described above.

The annealed film typically has an increased density and/or reduced thickness versus that of the wet precursor layer. In some embodiments, the film thicknesses of the dried and annealed coatings are 0.1-200 microns; 0.1-100 microns; 0.1-50 microns; 0.1-25 microns; 0.1-10 microns; 0.1-5 microns; 0.1-3 microns; 0.3-3 microns; or 0.5-2 microns.

Purification of Coated Layers and Films.

Application of multiple coatings, washing the coating, and/or exchanging capping agents can serve to reduce carbon-based impurities in the coatings and films. For example, after an initial coating, the coated substrate can be dried and then a second coating can be applied and coated by spin-coating. The spin-coating step can wash organics out of the first coating. Alternatively, the coated film can be soaked in a solvent and then spun to wash out the organics. Examples of useful solvents for removing organics in the coatings include alcohols, e.g., methanol or ethanol, and hydrocarbons, e.g., toluene. As another example, dip-coating the substrate into the ink can be alternated with dip-coating the coated substrate into a bath to remove impurities and capping agents. Removal of non-volatile capping agents from the coating can be further facilitated by exchanging these capping agents with volatile capping agents. For example, the volatile capping agent can be used as the washing solution or as a component in a bath. In some embodiments, a layer of a coated substrate comprising a first capping agent is contacted with a second capping agent, thereby replacing the first capping agent with the second capping agent to form a second coated substrate. Advantages of this method include film densification, along with lower levels of carbon-based impurities in the film, particularly if and when it is later annealed. Alternatively, binary sulfides and other impurities can be removed by etching the annealed film using standard techniques for CIGS/Se films.

### Preparation of Devices, Including Thin-Film Photovoltaic Cells

Another aspect of this invention is a photovoltaic cell comprising a film, wherein the film comprises:

a) an inorganic matrix; and
b) CIGS/Se microparticles characterized by an average longest dimension of 0.5-200 microns, wherein the microparticles are embedded in the inorganic matrix.

Another aspect of this invention is a process for preparing a photovoltaic cell comprising a film comprising CIGS/Se microparticles characterized by an average longest dimension of 0.5-200 microns, wherein the microparticles are embedded in an inorganic matrix.

Various embodiments of the film are as described above. In some embodiments, the film is the absorber or buffer layer of a photovoltaic cell.

Various electrical elements can be formed, at least in part, by the use of the inks and processes described herein. One aspect of this invention provides a process for making an electronic device and comprises depositing one or more layers in layered sequence onto the annealed coating of the substrate. The layers can be selected from the group consisting of: conductors, semiconductors, and insulators.

Another aspect of this invention provides a process for manufacturing thin-film photovoltaic cells comprising CIGS/Se. A typical photovoltaic cell includes a substrate, a back contact layer (e.g., molybdenum), an absorber layer (also referred to as the first semiconductor layer), a buffer layer (also referred to as the second semiconductor layer), and a top contact layer. The photovoltaic cell can also include an electrode pad on the top contact layer, and an anti-reflective (AR) coating on the front (light-facing) surface of the substrate to enhance the transmission of light into the semiconductor layer. The buffer layer, top contact layer, electrode pads and antireflective layer can be deposited onto the annealed CIGS/Se film in layered sequence.

In one embodiment, the process provides a photovoltaic device and comprises depositing the following layers in layered sequence onto the annealed coating of the substrate having an electrically conductive layer present: (i) a buffer layer; (ii) a transparent top contact layer, and (iii) optionally, an antireflective layer. In yet another embodiment, the process provides a photovoltaic device and comprises disposing one or more layers selected from the group consisting of buffer layers, top contact layers, electrode pads, and antireflective layers onto the annealed CIGS/Se film. In some embodiments, construction and materials for these layers are analogous to those known in the art for a CIGS photovoltaic cell. Suitable substrate materials for the photovoltaic cell substrate are as described above.

### Industrial Utility

Advantages of the inks of the present invention are numerous: 1. The copper-, indium-, and gallium-containing elemental and chalcogenide particles are easily prepared and, in some cases, commercially available. 2. Combinations of the molecular precursor with CIGS/Se, elemental or chalcogenide particles, particularly nanoparticles, can be prepared that form stable dispersions that can be stored for long periods without settling or agglomeration, while keeping the amount of dispersing agent in the ink at a minimum. 3. The incorporation of elemental particles in the ink can minimize cracks and pinholes in the films and lead to the formation of annealed CIGS/Se films with large grain size. 4. The overall ratios of copper, indium, gallium and chalcogenide in the precursor ink, as well as the sulfur/selenium ratio, can be easily varied to achieve optimum performance of the photovoltaic cell. 5. The use of molecular precursors and/or nanoparticles enables lower annealing temperatures and denser film packing, while the incorporation of microparticles enables the inclusion of larger grain sizes in the film, even with relatively low annealing temperatures. 6. The ink can be prepared and deposited using a small number of operations and scalable, inexpensive processes. 7. Coatings derived from the ink described herein can be annealed at atmospheric pressure. Moreover, for certain ink compositions, only an inert atmosphere is required. For other ink compositions, the use of H₂S or H₂Se is not required to form CIGS/Se, since sulfurization or selenization can be achieved with sulfur or selenium vapor.

In some instances, the film described herein comprises CIGS/Se microparticles embedded in an inorganic matrix. Potential advantages of solar cells made from these layers are similar to those of traditional monograin solar cells, wherein the matrix comprises an organic insulator. That is, the CIGS/Se microparticles are fabricated separately from cell production at high temperatures and contribute large grains to the absorber layer, while the molecular and nanoparticle precursors enable low-temperature fabrication of the absorber layer. As compared to an organic matrix, the inorganic matrix potentially offers greater heat, light, and/or moisture stability and an additive effect in capturing light and converting it to current. Another advantage is that such films are less prone to cracking.

### Characterization

Useful analytical techniques for characterizing the composition, size, size distribution, density, and crystallinity of the metal chalcogenide nanoparticles, crystalline multinary-metal chalcogenide particles and layers of the present invention include XRD, XAFS (XAS), EDAX, ICP-MS, DLS, AFM, SEM, TEM, ESC, and SAX.

The following is a list of abbreviations and trade names used above and in the Examples:

| Abbreviation | Description |
|---|---|
| XRD | X-Ray Diffraction |
| TEM | Transmission Electron Microscopy |
| ICP-MS | Inductively Coupled Plasma Mass Spectrometry |
| AFM | Atomic Force Microscopy |
| DLS | Dynamic Light Scattering |
| SEM | Scanning Electron Microscopy |
| SAX | Small Angle X-ray Scattering |
| EDX | Energy-Dispersive X-ray Spectroscopy |
| XAFS | X-Ray Absorption Fine Structure |
| CIGS/Se | Copper-Indium-Gallium-Sulfo-di-selenide |
| Ex | Example |
| RTA | Rapid Thermal Annealing |
| TEA | Triethanolamine |
| TAA | Thioacetamide |

### EXAMPLES

### General

Materials.

All reagents were purchased from Aldrich (Milwaukee, Wis.), Alfa Aesar (Ward Hill, Mass.), TCI (Portland, Oreg.), or Gelest (Morrisville, Pa.). Solid reagents were used without further purification. Liquid reagents that were not packaged under an inert atmosphere were degassed by bubbling argon through the liquid for 1 hr. Anhydrous solvents were used for the preparation of all formulations and for all cleaning procedures carried out within the drybox. Solvents were either purchased as anhydrous from Aldrich or Alfa Aesar, or purified by standard methods (e.g., Pangborn, A. G., et al., Organometallics, 1996, 15, 1518-1520) and then stored in the drybox over activated molecular sieves.

Formulation and Coating Preparations.

Substrates (SLG slides) were cleaned sequentially with aqua regia, Miilipore® water and isopropanol, dried at 110° C., and coated on the non-float surface of the SLG substrate. All formulations and coatings were prepared in a nitrogen-purged drybox. Vials containing formulations were heated and stirred on a magnetic hotplate/stirrer. Coatings were dried in the drybox.

Annealing of Coated Substrates in a Tube Furnace.

Annealings were carried out either under an inert atmosphere (nitrogen or argon) or under an inert atmosphere comprising a chalcogen source (nitrogen/sulfur or argon/sulfur). Annealings were carried out in either a single-zone Lindberg/Blue tube furnace (Ashville, N.C.) equipped with an external temperature controller and a one-inch quartz tube, or in a Lindberg/Blue three-zone tube furnace (Model STF55346C) equipped with a three-inch quartz tube. A gas inlet and outlet were located at opposite ends of the tube, and the tube was purged with nitrogen or argon while heating and cooling. The coated substrates were placed on quartz plates inside of the tube.

When annealing under sulfur, a 3-inch long ceramic boat was loaded with 2.5 g of elemental sulfur and placed near the gas inlet, outside of the direct heating zone. The coated substrates were placed on quartz plates inside the tube.

### Details of the Procedures Used for Device Manufacture

Mo-Sputtered Substrates.

Substrates for photovoltaic devices were prepared by coating an SLG substrate with a 500 nm layer of patterned molybdenum using a Denton Sputtering System. Deposition conditions were: 150 watts of DC Power, 20 sccm Ar, and 5 mT pressure.

Cadmium Sulfide Deposition.

CdSO₄ (12.5 mg, anhydrous) was dissolved in a mixture of nanopure water (34.95 mL) and 28% NH₄OH (4.05 mL). Then a 1 mL aqueous solution of 22.8 mg thiourea was added rapidly to form the bath solution. Immediately upon mixing, the bath solution was poured into a double-walled beaker (with 70° C. water circulating between the walls), which contained the samples to be coated. The solution was continuously stirred with a magnetic stir bar. After 23 min, the samples were taken out, rinsed with and then soaked in nanopure water for an hour. The samples were dried under a nitrogen stream and then annealed under a nitrogen atmosphere at 200° C. for 2 min.

Insulating ZnO and AZO Deposition.

A transparent conductor was sputtered on top of the CdS with the following structure: 50 nm of insulating ZnO (150 W RF, 5 mTorr, 20 sccm) followed by 500 nm of Al-doped ZnO using a 2% Al₂O₃, 98% ZnO target (75 or 150 W RF, 10 mTorr, 20 sccm).

ITO Transparent Conductor Deposition.

A transparent conductor was sputtered on top of the CdS with the following structure: 50 nm of insulating ZnO [100 W RF, 20 mTorr (19.9 mTorr Ar+0.1 mTorr O₂)] followed by 250 nm of ITO [100 W RF, 12 mTorr (12 mTorr Ar+5×10⁻⁶ Torr O₂)]. The sheet resistivity of the resulting ITO layer is around 30 ohms per square.

Deposition of Silver Lines.

Silver was deposited at 150 WDC, 5 mTorr, 20 sccm Ar, with a target thickness of 750 nm.

### Details of X-Ray, IV, EQE, and OBIC Analysis.

XRD Analysis.

Powder X-ray diffraction was used to identify crystalline phases. Data were obtained with a Philips X′PERT automated powder diffractometer, Model 3040. The diffractometer was equipped with automatic variable anti-scatter and divergence slits, X′Celerator RTMS detector, and Ni filter. The radiation was CuK(alpha) (45 kV, 40 mA). Data were collected at room temperature from 4 to 120°. 2-theta, using a continuous scan with an equivalent step size of 0.02°, and a count time of from 80 sec to 240 sec per step in theta-theta geometry. Thin film samples were presented to the X-ray beam as made. MDI/Jade software version 9.1 was used with the International Committee for Diffraction Data database PDF4+ 2008 for phase identification and data analysis.

IV Analysis.

Current (I) versus voltage (V) measurements were performed on the samples using two Agilent 5281B precision medium power SMUs in a E5270B mainframe in a four point probe configuration. Samples were illuminated with an Oriel 81150 solar simulator under 1 sun AM 1.5G.

EQE Analysis.

External Quantum Efficiency (EQE) determinations were carried out as described in ASTM Standard E1021-06 (“Standard Test Method for Spectral Responsivity Measurements of Photovoltaic Devices”). The reference detector in the apparatus was a pyroelectric radiometer (Laser Probe (Utica, N.Y.), LaserProbe Model RkP-575 controlled by a LaserProbe Model Rm-6600 Universal Radiometer). The excitation light source was a xenon arc lamp with wavelength selection provided by a monochrometer in conjunction with order sorting filters. Optical bias was provided by a broad band tungsten light source focused to a spot slightly larger than the monochromatic probe beam. Measurement spot sizes were approximately 1 mm×2 mm.

OBIC Analysis.

Optical beam induced current measurements were determined with a purpose-constructed apparatus employing a focused monochromatic laser as the excitation source. The excitation beam was focused to a spot ˜100 microns in diameter. The excitation spot was rastered over the surface of the test sample while simultaneously measuring photocurrent so as to build a map of photocurrent vs position for the sample. The resulting photocurrent map characterizes the photoresponse of the device vs. position. The apparatus can operate at various wavelengths via selection of the excitation laser. Typically, 440, 532 or 633 nm excitation sources were employed.

Synthesis and Characterization of CIS Particles.

Aqueous stock solutions were prepared in nanopure water. Solutions of CuSO₄ (2.0 mmol, 0.4 M) and InCl₃(1.0 mmol, 0.4 M) were mixed together in a round bottom flask equipped with a stir bar. Next, solutions of NH₄NO₃ (1 mmol, 0.4 M) and triethanolamine (TEA, 4 mmol, 3.7 M) were sequentially added to the reaction mixture. Sulfuric acid was used to adjust the pH to 1, and the reaction mixture was stirred for 30 min, followed by the addition of aqueous thioacetamide (TAA, 20 mmol, 0.4 M). The flask was placed in a hot water bath with magnetic stirring and the reaction temperature was maintained at 80° C. for 2.5 h to provide a black suspension. Next, the water bath was removed, and the flask was allowed to cool to room temperature. The resulting precipitate was collected via decantation/centrifugation. The solids were washed three times with water. The water-washed solids were dried overnight in a vacuum oven at 45° C. to provide a black powder (the as-synthesized nanoparticles). The nanoparticles were heated at 550° C. under nitrogen for 3 h to provide high purity copper indium sulfide particles (CuInS₂), as indicated by XRD.

### Example 1

This example illustrates: (a) the preparation of an ink from a combination of molecular precursor and CIS particles, synthesized as described above by an aqueous route; (b) the formation of an annealed film of CIS₂ from the molecular precursor/particle ink using only an inert gas in the annealing atmosphere; and (c) the production of an active photovoltaic device from an annealed film of the molecular precursor/particle-containing ink (Example 1A). The device exhibited improved EQE at 640 nm over a device made from a film of the molecular precursor alone (Comparative Examples 1B and 1C).

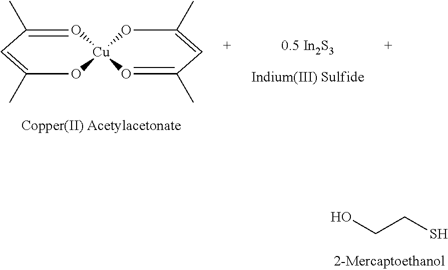

Copper(II) acetylacetonate (0.4270 g, 1.631 mmol) and indium(III) sulfide (0.2659 g, 0.816 mmol) were placed together in a 40 mL amber septum-capped vial equipped with a stir bar. A 3:2 solution (1.5 g) of 5-ethyl-2-methylpyridine and 2-aminopyridine, 2-mercaptoethanol (0.2934 g, 3.755 mmol), and sulfur (0.0528 g, 1.646 mmol) were sequentially added with mixing. The molecular precursor reaction mixture was stirred for ˜72 h at a first heating temperature of 100° C. Next, the reaction mixture was stirred for ˜24 h at a second heating temperature of 170° C. A portion of the resulting mixture (1.0212 g) and CIS microparticles (0.1575 g) were placed in a 40 mL septum-capped amber vial equipped with a stir bar. The resulting mixture was stirred at a temperature of 100° C. for ˜24 h to form an ink.

The ink was spun-coated onto an SLG slide at 1500 rpm for 10 sec. The coating was then dried in the drybox on a hotplate at 170° C. for 15 min and then at 230° C. for 5 min. The dried film was then annealed under argon in a 3-inch tube furnace by heating to 250° C. at a rate of 15° C./min and then heating to 500° C. at a rate of 2° C./min. The temperature was then held at 500° C. for 1 hr. Analysis of the annealed sample by XRD indicated the presence of one crystalline phase: CIS₂.

### Example 1A

Example 1 was repeated with the exception that the ink was deposited on a Mo-patterned SLG slide. Cadmium sulfide, insulating ZnO, ITO, and silver lines were deposited. The device efficiency was 0.034%. Analysis by OBIC at 440 nm gave a photoresponse with J90 of 1.9 micro-Amp and dark current of 0.2 micro-Amp. The EQE onset was at 860 nm with an EQE of 3.81% at 640 nm.

### Comparative Example 1B

A portion of the molecular precursor alone was spun-coated onto an SLG slide at 2,250 rpm for 10 sec. The coating was then dried in the drybox on a hotplate at 170° C. for 15 min and then at 230° C. for 5 min. The coating (3,500 rpm for 10 sec) and drying procedures were repeated. The dried film was then annealed under argon in a 3-inch tube furnace by heating to 250° C. at a rate of 15° C./min and then heating to 500° C. at a rate of 2° C. min. The temperature was then held at 500° C. for 1 h. Analysis of the annealed sample by XRD indicated the presence of one crystalline phase: CIS₂.

### Comparative Example 1C

Comparative Example 1B was repeated with the exception that the ink was deposited on a Mo-patterned SLG slide. Cadmium sulfide, insulating ZnO, ITO, and silver lines were deposited. The device efficiency was 0.017%. Analysis by OBIC at 440 nm gave a photoresponse with J90 of 3.2 micro-Amp and dark current of 0.25 micro-Amp. The EQE onset was at 860 nm with an EQE of 0.48% at 640 nm.

### Example 2

This example illustrates: (a) the preparation of an ink in which the particles have a different composition than the molecular precursor. The ink is formed from CIS/Se molecular precursor and CIS particles, prepared as described above by an aqueous synthesis. This example also illustrates: (b) the formation of an annealed film of CISe₂ and CIS₂ from the molecular precursor/particle ink using only an inert gas in the annealing atmosphere.

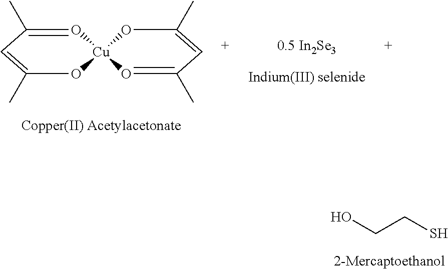

Molecular Precursor:

Copper(II) acetylacetonate (0.4317 g, 1.649 mmol), indium(III) selenide (0.3898 g, 0.836 mmol), 1.5 g of a 2:1 solution of 4-t-butylpyridine and 2-aminopyridine, 2-mercaptoethanol (0.2700 g, 3.456 mmol), and sulfur (0.0256 g, 0.7983 mmol) were combined and heated following the procedures of Example 1. The resulting molecular precursor was spun-coated onto an SLG slide at 2,250 rpm for 10 sec. The coating was then dried in the drybox on a hotplate at 170° C. for 15 min and then at 230° C. for 5 min. The coating (3,250 rpm for 10 sec) and drying procedures were repeated. The dried film was then annealed under argon in a 3-inch tube furnace by heating to 250° C. at a rate of 15° C./min and then heating to 500° C. at a rate of 2° C./min. The temperature was then held at 500° C. for 1 hr. Analysis of the annealed film by XRD indicated the presence of CuInSe₂, Cu_{0.79}In_{0.78}Se_{1.8}, and two forms of CuInS₂, along with small amounts of CuS, Se, and S₆.

Prophetic Portion of Example 2:

A portion (1.0 g) of the molecular precursor, prepared as described above from copper(II) acetylacetonate, indium(III) selenide, and 2-mercaptoethanol, is combined with CIS particles (0.16 g), prepared as described above from an aqueous synthesis, in a 40 mL septum-capped amber vial equipped with a stir bar. The resulting mixture is stirred at a temperature of 100° C. for ˜24 h to give an ink of CIS/Se molecular precursor and CIS particles. A film of the ink is formed on a SLG slide by following the coating, drying, and annealing procedures given above.

What is claimed is:

1. An ink comprising:
a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof; and
b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

2. The ink of claim 1, wherein at least one of the molecular precursor or the ink has been heat-processed at a temperature of greater than about 90° C.

3. The ink of claim 1, wherein the molar ratio of Cu:(In+Ga) is about 1 in the ink.

4. The ink of claim 1, wherein the molar ratio of total chalcogen to (Cu+In+Ga) in the ink is at least about 1.

5. The ink of claim 1, wherein the molecular precursor comprises a chalcogen compound.

6. The ink of claim 1, wherein the molecular precursor comprises a chalcogen compound selected from the group consisting of: elemental S, elemental Se, CS₂, CSe₂, CSSe, R¹S—Z, R¹Se—Z, R¹S—SR¹, R¹Se—SeR¹, R²C(S)S—Z, R²C(Se)Se—Z, R²C(Se)S—Z, R¹C(O)S—Z, R¹C(O)Se—Z, and mixtures thereof,
wherein each Z is independently selected from the group consisting of: H, NR⁴₄, and SiR⁵₃;
wherein each R¹ and R⁵ is independently selected from the group consisting of: hydrocarbyl and O-, N-, S-, Se-, halogen- or tri(hydrocarbyl)silyl-substituted hydrocarbyl;
each R² is independently selected from the group consisting of hydrocarbyl, O-, N-, S-, Se-, halogen-, or tri(hydrocarbyl)silyl-substituted hydrocarbyl, and O-, N-, S-, or Se-based functional groups; and
each R⁴ is independently selected from the group consisting of hydrogen, O-, N-, S-, Se-, halogen- or tri(hydrocarbyl)silyl-substituted hydrocarbyl, and O-, N-, S-, or Se-based functional groups.

7. The ink of claim 1, wherein the nitrogen-, oxygen-, carbon-, sulfur-, or selenium-based organic ligands are selected from the group consisting of: amidos; alkoxides; acetylacetonates; carboxylates; hydrocarbyls; O-, N-, S-, Se-, halogen-, or tri(hydrocarbyl)silyl-substituted hydrocarbyls; thiolates and selenolates; thio-, seleno-, and dithiocarboxylates; dithio-, diseleno-, and thioselenocarbamates; and dithioxanthogenates.

8. A coated substrate comprising:
A) a substrate; and
B) at least one layer disposed on the substrate comprising:
a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof; and
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

9. A process comprising disposing an ink onto a substrate to form a coated substrate, wherein the ink comprises:
a) a molecular precursor to CIGS/Se, comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof; and
b) a plurality of particles selected from the group consisting of: CIGS/Se particles; elemental Cu-, In-, or Ga-containing particles; binary or ternary Cu-, In-, or Ga-containing chalcogenide particles; and mixtures thereof.

10. The process of claim 9, further comprising an annealing step at about 350° C. to about 800° C., and wherein the annealing comprises thermal processing, rapid thermal processing, rapid thermal annealing, pulsed thermal processing, laser beam exposure, heating via IR lamps, electron beam exposure, pulsed electron beam processing, heating via microwave irradiation, or combinations thereof.

11. The process of claim 10, wherein the annealing is carried out under an atmosphere comprising an inert gas and a chalcogen source.

12. The process of claim 10, wherein the annealing is carried out under an atmosphere comprising an inert gas; and wherein the molar ratio of total chalcogen to (Cu+In+Ga) in the ink is at least about 1.

13. The process of claim 11, further comprising disposing one or more layers selected from the group consisting of buffer layers, top contact layers, electrode pads, and antireflective layers onto the annealed CIGS/Se film in layered sequence.

14. A film comprising:
a) an inorganic matrix; and
b) CIGS/Se microparticles characterized by an average longest dimension of 0.5-200 microns, wherein the microparticles are embedded in the inorganic matrix.

15. A photovoltaic cell comprising the film of claim 14.
